(19) United States
(12) Patent Application Publication
(10) Pub. No.: US 2026/0002738 A1
(43) Pub. Date: Jan. 1, 2026

(54) HEAT PIPE AND HEAT SINK

(71) Applicant: Furukawa Electric Co., Ltd., Tokyo (JP)

(72) Inventors: Masato WATANABE, Tokyo (JP); Tatsuro MIURA, Tokyo (JP); Kenya KAWABATA, Tokyo (JP)

(73) Assignee: Furukawa Electric Co., Ltd., Tokyo (JP)

(21) Appl. No.: 19/316,897

(22) Filed: Sep. 2, 2025

Related U.S. Application Data
(63) Continuation of application No. PCT/JP2024/008177, filed on Mar. 5, 2024.

(30) Foreign Application Priority Data
Mar. 6, 2023 (JP) 2023-033683

(51) Int. Cl. F28D 15/04; F28D 21/00

(52) U.S. Cl. CPC F28D 15/046; F28D 2021/0029

(57) ABSTRACT

A heat pipe including: a container including one end portion and another end portion opposite the one end portion, an end face of the one end portion and an end face of the other end portion being sealed; a wick structural body provided inside the container; and a working fluid encapsulated inside the container, wherein the wick structural body includes a fine groove provided on an inner surface of the container and/or a porous body provided on the inner surface of the container, and the working fluid contains hydrofluoroolefin.

### CROSS REFERENCE TO RELATED APPLICATIONS

The present application is a continuation application of International Patent Application No. PCT/JP2024/008177 filed on Mar. 5, 2024, which claims the benefit of Japanese Patent Application No. 2023-033683, filed on Mar. 6, 2023. The contents of these applications are incorporated herein by reference in their entirety.

### TECHNICAL FIELD

The present disclosure relates to a heat pipe that can prevent freezing of a working fluid and exhibit excellent circulation characteristics even in a low-temperature operating environment, and a heat sink including the heat pipe.

### DESCRIPTION OF THE RELATED ART

Electronic components such as semiconductor elements mounted in electric and electronic devices like laptop personal computers, servers, and data centers, as well as electronic components such as power semiconductors mounted in power control instruments of trains and the like generate increasing amounts of heat due to higher functionality and the like, and their cooling is becoming even more important. A heat pipe is used as cooling means of electronic components in some cases. Water is used as a working fluid of the heat pipe in some cases.

However, the heat pipe is used in a low-temperature environment in a configuration in which a heat-generating body that is a cooling target of the heat pipe is mounted in equipment exposed to the external environment. When the heat pipe is used in a low-temperature environment, there is a problem that water as the working fluid freezes, the heat pipe does not sufficiently operate, and the heat transfer function of the heat pipe degrades.

Furthermore, recently, reduction of environmental impact has been increasingly required. From the above description, a heat pipe used in a low-temperature environment is required to use a working fluid that is environmentally friendly and capable of preventing freezing even in a low-temperature environment.

A gravity heat pipe using hydrofluoroolefin as a working fluid that is environmentally friendly and capable of preventing freezing even in a low-temperature environment has been disclosed (Japanese Unexamined Patent Application Publication (Translation of PCT Application) No. 2022-537644). The gravity heat pipe of Japanese Unexamined Patent Application Publication (Translation of PCT Application) No. 2022-537644 is a loop-type heat pipe in which the working fluid having undergone a phase change from the liquid phase to the vapor phase at an evaporator circulates from the evaporator to a condenser through a vapor pipe and the working fluid having undergone a phase change from the vapor phase to the liquid phase by discharging latent heat at the condenser returns from the condenser to the evaporator through a liquid return pipe. In other words, in Japanese Unexamined Patent Application Publication (Translation of PCT Application) No. 2022-537644, the working fluid in the liquid phase returns from the condenser to the evaporator by the action of gravity.

However, as for the loop-type heat pipe of Japanese Unexamined Patent Application Publication (Translation of PCT Application) No. 2022-537644, it is needed to install the heat pipe so that the working fluid in the liquid phase circulates from the upper side to the lower side in the direction of gravity, and furthermore, a site where the working fluid in the vapor phase circulates and a site where the working fluid in the liquid phase circulates need to be separated from each other, and accordingly, there have been a problem that the flexibility of installation of the heat pipe is significantly restricted, and a problem that space saving is impossible and mounting in a narrow space is impossible.

In addition, in Japanese Unexamined Patent Application Publication (Translation of PCT Application) No. 2022-537644, with a configuration in which the vapor pipe and the liquid return pipe share a single pipe to prevent the flexibility of installation of the heat pipe from being restricted, the working fluid in the vapor phase and the working fluid in the liquid phase circulate inside the shared pipe in a counterflow manner, which has caused a problem that circulation of the working fluid is encumbered.

### SUMMARY

### Technical Problem

In view of the above-described situation, it is an object of the present disclosure to provide a heat pipe that can prevent freezing of a working fluid and exhibit excellent circulation characteristics even in a low-temperature operating environment and allows for space saving and improvement of flexibility of installation, and a heat sink including the heat pipe.

The gist of the configuration of the present disclosure is as follows.

{1} A heat pipe comprising:
a container including one end portion and another end portion opposite the one end portion, an end face of the one end portion and an end face of the other end portion being sealed;
a wick structural body provided inside the container; and
a working fluid encapsulated inside the container, wherein
the wick structural body includes a fine groove provided on an inner surface of the container and/or a porous body provided on the inner surface of the container, and
the working fluid contains hydrofluoroolefin.

{2} The heat pipe according to {1}, wherein the hydrofluoroolefin is at least one selected from the group consisting of cis-1,3,3,3-tetrafluoroprop-1-ene, trans-1,3,3,3-tetrafluoroprop-1-ene, 2,3,3,3-tetrafluoropropene, (Z)-1,1,1,4,4,4-hexafluorobutene, (E)-1,1,1,4,4,4-hexafluorobutene, trans-1-chloro-3,3,3-trifluoropropene, (Z)-1-chloro-3,3,3-trifluoropropene, and 1-chloro-2,3,3-trifluoropropene.

{3} The heat pipe according to {1}, wherein the hydrofluoroolefin is trans-1,3,3,3-tetrafluoroprop-1-ene.

{4} The heat pipe according to any one of {1} to {3}, wherein a temperature of a critical point of the working fluid is equal to or higher than 100° C.

{5} The heat pipe according to any one of {1} to {3}, wherein the working fluid is hydrofluoroolefin.

{6} The heat pipe according to any one of {1} to {3}, wherein the working fluid contains hydrofluoroolefin, water, and/or alcohol.

{7} The heat pipe according to any one of {1} to {3}, wherein the container is a tubular body and an inner diameter of the container is equal to or larger than 3.0 mm and equal to or smaller than 32 mm.

{8} The heat pipe according to any one of {1} to {3}, wherein a shape of the container in a longitudinal direction includes a bent section. {9} The heat pipe according to any one of {1} to {3}, wherein the container is planar.

{10} The heat pipe according to any one of {1} to {3}, wherein the working fluid has a cross-sectional area that is 50% or more of a cross-sectional area of an internal space of the container in at least one section among sections in a direction orthogonal to a longitudinal direction of the container when a shape of the container in the longitudinal direction is straight and the longitudinal direction of the container is a direction orthogonal to a direction of gravity.

{11} The heat pipe according to any one of {1} to {3}, wherein the working fluid has a cross-sectional area that is 50% or more of a cross-sectional area of an internal space of a straight section in at least one section among sections in a direction orthogonal to a longitudinal direction of the straight section when a shape of the container in the longitudinal direction is a shape including the straight section and a bent section and the longitudinal direction of the straight section is a direction orthogonal to a direction of gravity.

{12} The heat pipe according to {11}, wherein the straight section is a site to which a heat-generating body that is a cooling target is thermally connected.

{13} The heat pipe according to any one of {1} to {3}, wherein a material of the container is copper, a copper alloy, aluminum, an aluminum alloy, stainless steel, titanium, or a titanium alloy.

{14} The heat pipe according to any one of {1} to {3}, wherein the wick structural body is a fine groove provided on the inner surface of the container, and the shape of the fine groove in a direction orthogonal to a longitudinal direction of the container is a rectangular shape, a triangular shape, or a trapezoidal shape.

{15} The heat pipe according to {14}, wherein the shape of the fine groove is a rectangular shape, a depth (H) of the fine groove is equal to or larger than 0.15 mm and equal to or smaller than 0.50 mm, and a width (W) of the fine groove is equal to or larger than 0.15 mm and equal to or smaller than 0.60 mm.

{16} The heat pipe according to {14}, wherein the shape of the fine groove is a triangular shape, a depth (H) of the fine groove is equal to or larger than 0.15 mm and equal to or smaller than 0.50 mm, and a width (W) of the fine groove at a site ((½)H) of ½ of the depth (H) is equal to or larger than 0.15 mm and equal to or smaller than 1.00 mm.

{17} The heat pipe according to {14}, wherein the shape of the fine groove is a trapezoidal shape, a depth (H) of the fine groove is equal to or larger than 0.15 mm and equal to or smaller than 0.50 mm, and an average value of a width (W) of the fine groove is equal to or larger than 0.05 mm and equal to or smaller than 1.00 mm.

{18} The heat pipe according to any one of {1} to {3}, wherein a heat-receiving block is further thermally connected to a partial region of the container.

{19} The heat pipe according to any one of {1} to {3}, wherein a temperature of an operating environment is equal to or higher than −50° C. and equal to or lower than 90° C.

{20} A heat sink comprising:
the heat pipe according to any one of {1} to {3}; and
heat-releasing fins thermally connected to a first region that is a partial region of the container of the heat pipe.

{21} The heat sink according to {20}, wherein a heat-receiving block is further thermally connected to a second region that is another partial region of the container.

{22} The heat sink according to {20}, wherein a temperature of an operating environment is equal to or higher than −50° C. and equal to or lower than 90° C.

{23} The heat sink according to {20}, further comprising a heat pipe with water as the working fluid.

{24} The heat sink according to {23}, wherein an inclination angle of the heat pipe with water as the working fluid is 5° to 12°.

{25} The heat sink according to {20}, wherein spacing between the heat-releasing fins is wider on a tip end side of the heat pipe than on a bottom side of the heat pipe.

“The working fluid has a cross-sectional area that is 50% or more of the cross-sectional area of the internal space of the container” and “the working fluid has a cross-sectional area that is 50% or more of the cross-sectional area of the internal space of the straight section” in the above-described aspects mean the cross-sectional area of the working fluid in a state in which no heat-generating body that is a cooling target is thermally connected to the heat pipe.

According to an aspect of a heat pipe of the present disclosure, since the working fluid contains hydrofluoroolefin, it is possible to prevent freezing of the working fluid and exhibit excellent circulation characteristics even in a low-temperature operating environment while reducing impact on environment. Moreover, according to an aspect of the heat pipe of the present disclosure, since the heat pipe includes: a container including one end portion and another end portion opposite the one end portion, an end face of the one end portion and an end face of the other end portion being sealed; a wick structural body provided inside the container; and a working fluid encapsulated inside the container, and the wick structural body includes a fine groove provided on an inner surface of the container and/or a porous body provided on the inner surface of the container, the heat pipe is not a loop type and circular current of the working fluid in the liquid phase due to the action of gravity is not essential, and thus space saving and improvement of flexibility of installation are possible.

According to an aspect of the heat pipe of the present disclosure, since the hydrofluoroolefin is at least one selected from the group consisting of cis-1,3,3,3-tetrafluoroprop-1-ene, trans-1,3,3,3-tetrafluoroprop-1-ene, 2,3,3,3-tetrafluoropropene, (Z)-1,1,1,4,4,4-hexafluorobutene, (E)-1,1,1,4,4,4-hexafluorobutene, trans-1-chloro-3,3,3-trifluoropropene, (Z)-1-chloro-3,3,3-trifluoropropene, and 1-chloro-2,3,3-trifluoropropene, it is possible to further reliably prevent freezing of the working fluid even in a low-temperature operating environment, and the heat transfer characteristics of the heat pipe improve.

According to an aspect of the heat pipe of the present disclosure, since the hydrofluoroolefin is trans-1,3,3,3-tetrafluoroprop-1-ene, the heat transfer characteristics of the heat pipe further improve.

According to an aspect of the heat pipe of the present disclosure, since the temperature of the critical point of the working fluid is equal to or higher than 100° C., it is possible to reliably achieve heat transfer characteristics even when an operating environment of the heat pipe is at a high temperature.

According to an aspect of the heat pipe of the present disclosure, since water and/or alcohol is contained in addition to the hydrofluoroolefin, it is possible to achieve even better heat transfer characteristics compared to a case where the working fluid is made of hydrofluoroolefin. Note that excellent heat transfer characteristics are heat transfer capacity and prevention of heat transfer capacity decrease caused by change of the container shape. Moreover, although water freezes at low temperature, melting of water is promoted by heat transfer action of hydrofluoroolefin since water and hydrofluoroolefin are used in combination, and thus it is possible to exhibit characteristics of water, which has excellent heat transfer characteristics.

According to an aspect of the heat pipe of the present disclosure, since the working fluid has a cross-sectional area that is 50% or more of the cross-sectional area of the internal space of the container in at least one section among sections in the direction orthogonal to the longitudinal direction of the container when the shape of the container in a longitudinal direction is straight and the longitudinal direction of the container is a direction orthogonal to the direction of gravity, the heat transfer characteristics of the heat pipe further improve.

A typical refrigerant containing hydrofluoroolefin has a smaller latent heat compared to water and a refrigerant mass necessary for transferring the same amount of heat is large, and thus there is a problem that the volume of refrigerant vapor that transfers the same heat amount is large and refrigerant circular current is largely encumbered. However, according to an aspect of the heat pipe of the present disclosure, since the working fluid has a cross-sectional area that is 50% or more of the cross-sectional area of the internal space of the straight section in at least one section among sections in the direction orthogonal to the longitudinal direction of the straight section when the shape of the container in a longitudinal direction is a shape including a straight section and a bent section and the longitudinal direction of the straight section is a direction orthogonal to the direction of gravity, the heat transfer characteristics of the heat pipe further improve.

According to an aspect of the heat pipe of the present disclosure, since the wick structural body is a fine groove provided on the inner surface of the container, and the shape of the fine groove in a direction orthogonal to a longitudinal direction of the container is a rectangular shape, a triangular shape, or a trapezoidal shape, it is possible to reliably achieve the circular current characteristics of the working fluid in the liquid phase while reliably obtaining a flow path through which the working fluid in the vapor phase circulates.

According to an aspect of the heat pipe of the present disclosure, since the shape of the fine groove is a rectangular shape, the depth (H) of the fine groove is equal to or larger than 0.15 mm and equal to or smaller than 0.50 mm, and the width (W) of the fine groove is equal to or larger than 0.15 mm and equal to or smaller than 0.60 mm, the circular current characteristics of the working fluid in the liquid phase improve and the heat transfer characteristics of the heat pipe further improve.

According to an aspect of the heat pipe of the present disclosure, since the shape of the fine groove is a triangular shape, the depth (H) of the fine groove is equal to or larger than 0.15 mm and equal to or smaller than 0.50 mm, and the width (W) of the fine groove at a site ((½)H) of ½ of the depth (H) is equal to or larger than 0.15 mm and equal to or smaller than 1.00 mm, the circular current characteristics of the working fluid in the liquid phase improve and the heat transfer characteristics of the heat pipe further improve.

According to an aspect of the heat pipe of the present disclosure, since the shape of the fine groove is a trapezoidal shape, the depth (H) of the fine groove is equal to or larger than 0.15 mm and equal to or smaller than 0.50 mm, and the average value of the width (W) of the fine groove is equal to or larger than 0.05 mm and equal to or smaller than 1.00 mm, the circular current characteristics of the working fluid in the liquid phase improve and the heat transfer characteristics of the heat pipe further improve.

According to an aspect of a heat sink of the present disclosure, since the heat pipe and a heat-releasing fins thermally connected to a first region that is a partial region of the container of the heat pipe are included, it is possible to prevent freezing of the working fluid of the heat pipe and exhibit excellent circulation characteristics of the working fluid even in a low-temperature operating environment, and space saving and improvement of flexibility of installation are possible.

### BRIEF DESCRIPTION OF DRAWINGS

FIG. 1 is an explanatory diagram illustrating an overview of a heat pipe according to a first example embodiment of the present disclosure in a longitudinal direction.

FIG. 2 is an explanatory diagram illustrating an overview of a section of the heat pipe according to the first example embodiment of the present disclosure in a direction orthogonal to the longitudinal direction.

FIG. 3 is an explanatory diagram of a first shape of a fine groove in the section of the heat pipe according to the first example embodiment of the present disclosure in the direction orthogonal to the longitudinal direction.

FIG. 4 is an explanatory diagram of a second shape of the fine groove in the section of the heat pipe according to the first example embodiment of the present disclosure in the direction orthogonal to the longitudinal direction.

FIG. 5 is an explanatory diagram of a third shape of the fine groove in the section of the heat pipe according to the first example embodiment of the present disclosure in the direction orthogonal to the longitudinal direction.

FIG. 6 is an explanatory diagram illustrating an overview of a heat pipe according to a second example embodiment of the present disclosure in a longitudinal direction.

FIG. 7 is an explanatory diagram illustrating an aspect of a heat pipe according to a third example embodiment of the present disclosure in plan view.

FIG. 8 is a plan view illustrating an overview of a heat sink according to a first example embodiment of the present disclosure.

FIG. 9 is a side view illustrating an overview of the heat sink according to the first example embodiment of the present disclosure.

FIG. 10 is a plan view illustrating an overview of a heat sink according to a second example embodiment of the present disclosure.

FIG. 11 is a side view illustrating the overview of the heat sink according to the second example embodiment of the present disclosure.

FIG. 12 is a plan view illustrating an overview of a heat sink according to a third example embodiment of the present disclosure.

FIG. 13 is a side view illustrating the overview of the heat sink according to the third example embodiment of the present disclosure.

FIG. 14 is a plan view illustrating an overview of a heat sink according to a fourth example embodiment of the present disclosure.

FIG. 15 is a side view illustrating the overview of the heat sink according to the fourth example embodiment of the present disclosure.

FIG. 16 is a plan view illustrating an overview of a heat sink according to a fifth example embodiment of the present disclosure.

FIG. 17 is a side view illustrating the overview of the heat sink according to the fifth example embodiment of the present disclosure.

FIG. 18 is a plan view illustrating an overview of a heat sink according to a sixth example embodiment of the present disclosure.

FIG. 19 is a side view illustrating the overview of the heat sink according to the sixth example embodiment of the present disclosure.

FIG. 20 is a plan view illustrating an overview of a heat sink according to a seventh example embodiment of the present disclosure.

FIG. 21 is a side view illustrating the overview of the heat sink according to the seventh example embodiment of the present disclosure.

FIG. 22 is a side view illustrating an overview of a heat sink according to an eighth example embodiment of the present disclosure.

FIG. 23 is a side view illustrating an overview of a heat sink according to a ninth example embodiment of the present disclosure.

### DETAILED DESCRIPTION

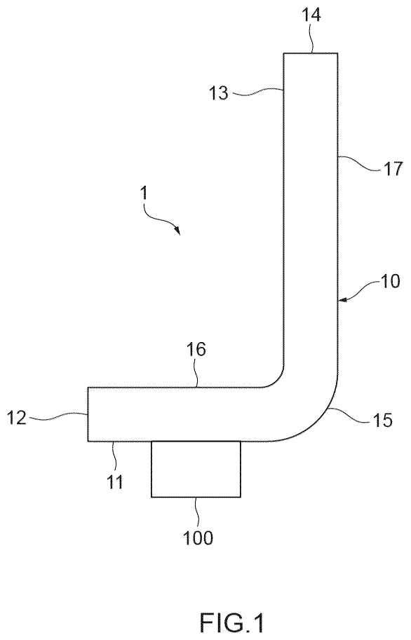

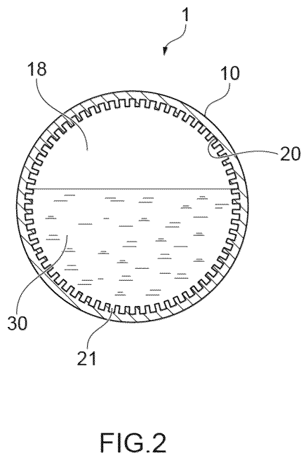

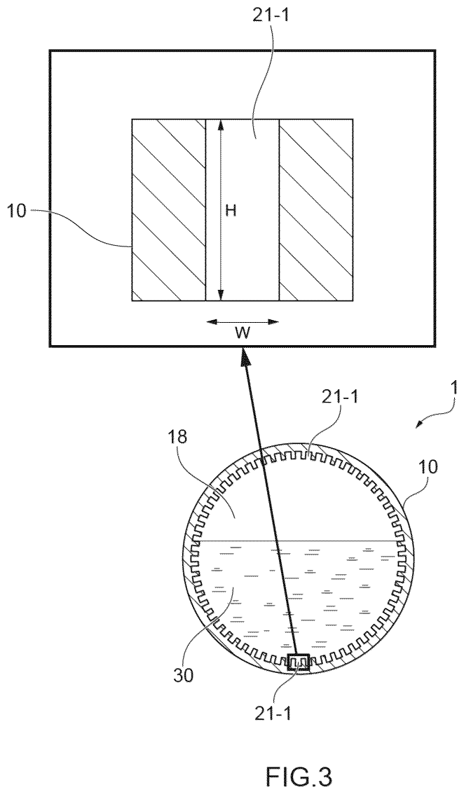

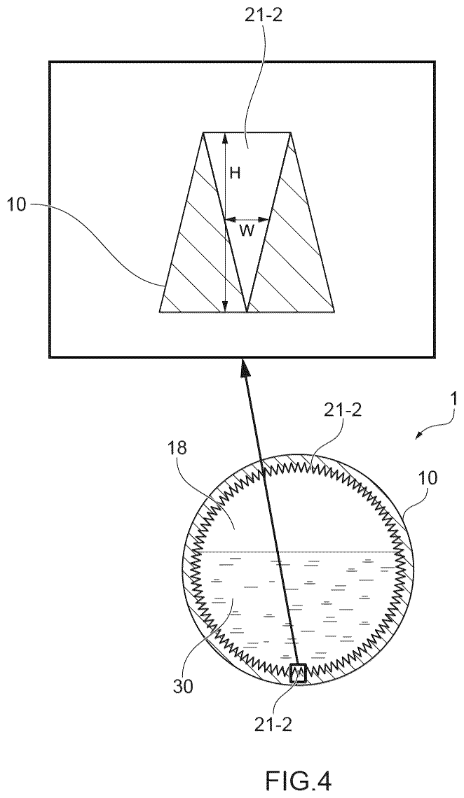

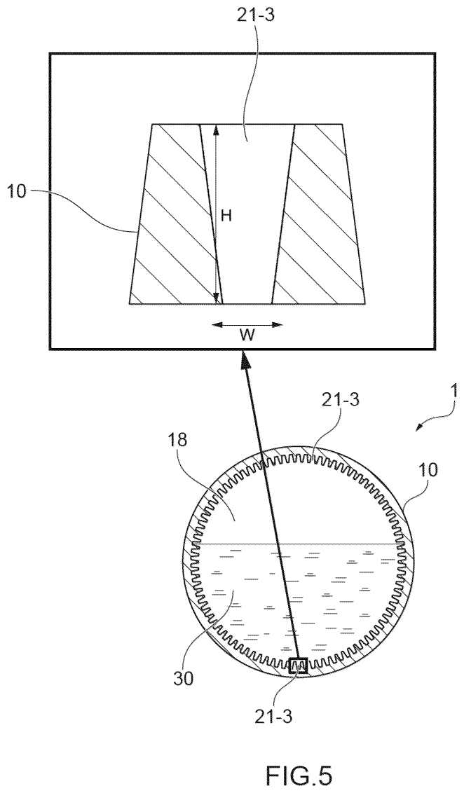

Hereinafter, a heat pipe according to a first example embodiment of the present disclosure will be described with reference to drawings. Note that FIG. 1 is an explanatory diagram illustrating an overview of the heat pipe according to the first example embodiment of the present disclosure in a longitudinal direction. FIG. 2 is an explanatory diagram illustrating an overview of a section of the heat pipe according to the first example embodiment of the present disclosure in a direction orthogonal to the longitudinal direction. FIG. 3 is an explanatory diagram of a first shape of a fine groove in the section of the heat pipe according to the first example embodiment of the present disclosure in the direction orthogonal to the longitudinal direction. FIG. 4 is an explanatory diagram of a second shape of the fine groove in the section of the heat pipe according to the first example embodiment of the present disclosure in the direction orthogonal to the longitudinal direction. FIG. 5 is an explanatory diagram of a third shape of the fine groove in the section of the heat pipe according to the first example embodiment of the present disclosure in the direction orthogonal to the longitudinal direction.

As illustrated in FIGS. 1 and 2, a heat pipe 1 according to the first example embodiment of the present disclosure includes: a container 10 including one end portion 11 and another end portion 13 opposite the one end portion 11, an end face 12 of the one end portion 11 and an end face 14 of the other end portion 13 being sealed; a wick structural body 20 provided inside the container 10; and a working fluid 30 encapsulated inside the container 10. From the above description, the heat pipe 1 is not a loop-type heat pipe, and the working fluid in the vapor phase and the working fluid in the liquid phase are in a relation of counterflow and circulate in a hollow section 18 that is the internal space of the same container 10. The hollow section 18 that is the internal space of the container 10 is a sealed space that is depressurized.

In the heat pipe of the present disclosure, the working fluid 30 encapsulated in the hollow section 18 contains hydrofluoroolefin. Thus, the heat pipe 1 contains hydrofluoroolefin as the working fluid 30.

In the heat pipe of the present disclosure, since the working fluid 30 contains hydrofluoroolefin, it is possible to prevent freezing of the working fluid 30 and exhibit excellent circulation characteristics even in a low-temperature operating environment while reducing impact on environment.

The hydrofluoroolefin is not particularly limited, but cis-1,3,3,3-tetrafluoroprop-1-ene (HFO-1234ze(Z), CH₃CH═CHF), trans-1,3,3,3-tetrafluoroprop-1-ene (HFO-1234ze(E), CH₃CH═CHF), 2,3,3,3-tetrafluoropropene (HFO-1234yf, CH₂—CFCF₃), (Z)-1,1,1,4,4,4-hexafluorobutene (HFO-1336mzz(Z), (Z)-CF₃CF═CHCF₃), (E)-1,1,1,4,4,4-hexafluorobutene (HFO-1336mzz(E), (E)-CF₃CF═CHCF₃), 1-chloro-2,3,3,3-tetrafluoropropene (HFO-1224 yd(Z), CF₃CF═CHCl), trans-1-chloro-3,3,3-trifluoropropene (HFO-1233zd(E), (E)-CF₃CH═CClH), (Z)-1-chloro-3,3,3-trifluoropropene (HFO-1233zd(Z), (Z)-CF₃CH═CHCl), 1-chloro-2,3,3-trifluoropropene (HFO-1233yd, CHCl═CFCF₃), or the like is preferable from the standpoint that it is possible to further reliably prevent freezing of the working fluid 30 even in a low-temperature operating environment and the heat transfer characteristics of the heat pipe 1 improve. These hydrofluoroolefins may be used alone or in combination of two or more.

Moreover, among the above-described hydrofluoroolefins, trans-1,3,3,3-tetrafluoroprop-1-ene is particularly preferable from the standpoint that the heat transfer characteristics of the heat pipe 1 further improve.

The temperature of the critical point of the working fluid 30 containing hydrofluoroolefin is not particularly limited but is preferably equal to or higher than 100° C. and particularly preferably equal to or higher than 105° C. from the standpoint that smooth phase transition between the vapor phase and the liquid phase is maintained and it is possible to reliably achieve the heat transfer characteristics of the heat pipe 1 even when the operating environment of the heat pipe 1 is at high temperature. The temperature of the critical point of cis-1,3,3,3-tetrafluoroprop-1-ene (HFO-1234ze(Z), CH₃CH═CHF) is 153° C., the temperature of the critical point of trans-1,3,3,3-tetrafluoroprop-1-ene (HFO-1234ze(E), CH₃CH═CHF) is 109° C., the temperature of the critical point of 2,3,3,3-tetrafluoropropene (HFO-1234yf, CH₂═CFCF₃) is 95° C., the temperature of the critical point of (Z)-1,1,1,4,4,4-hexafluorobutene (HFO-1336mzz(Z), (Z)-CF₃CF═CHCF₃) is 171° C., the temperature of the critical point of (E)-1,1,1,4,4,4-hexafluorobutene (HFO-1336mzz(E), (E)-CF₃CF═CHCF₃) is 138° C., the temperature of the critical point of 1-chloro-2,3,3,3-tetrafluoropropene (HFO-1224 yd(Z), CF₃CF═CHCl) is 156° C., and the temperature of the critical point of trans-1-chloro-3,3,3-trifluoropropene (HFO-1233zd(E), (E)-CF₃CH═CClH) is 165° C. Note that the upper limit value of the temperature of the critical point of hydrofluoroolefin is, for example, 180° C.

In the heat pipe of the present disclosure, the working fluid 30 only needs to contain hydrofluoroolefin. Thus, in the heat pipe 1, the working fluid 30 only needs to contain hydrofluoroolefin. From the above description, in the heat pipe of the present disclosure, the working fluid 30 may be made of hydrofluoroolefin only (in other words, the mixing ratio of hydrofluoroolefin in the working fluid 30 may be 100 mass %) or the working fluid 30 may contain hydrofluoroolefin and other fluid.

In a case where hydrofluoroolefin and other fluid are used in combination as the working fluid 30, the mixing ratio of hydrofluoroolefin in the working fluid 30 is preferably equal to or larger than 3 mass % and equal to or smaller than 70 mass % and particularly preferably equal to or larger than 3 mass % and equal to or smaller than 45 mass % from the standpoint to improve freezing prevention of the working fluid 30 and the heat transfer characteristics in a well-balanced manner. The other fluid that can be used in combination with hydrofluoroolefin is, for example, water, alcohol, or a mixture of water and alcohol. Since water and/or alcohol is contained in addition to hydrofluoroolefin as the working fluid 30, the heat pipe 1 can exhibit even better heat transfer characteristics compared to a case where the working fluid 30 is made of hydrofluoroolefin. Moreover, although water freezes at low temperature, melting of water is promoted by heat transfer action of hydrofluoroolefin since water and hydrofluoroolefin are used in combination as the working fluid 30, and thus it is possible to exhibit characteristics of water, which has excellent heat transfer characteristics. In a case where water and hydrofluoroolefin are used in combination as the working fluid 30, the mixing ratio of hydrofluoroolefin is preferably equal to or smaller than 30 mass % from the perspective of heat transfer characteristics.

As illustrated in FIG. 1, in the heat pipe 1, the container 10 is a tubular body. The shape of the container 10 is elongated. The shape of the container 10 in the longitudinal direction can be selected as appropriate in accordance with usage conditions and the like and may be straight or may be a shape including a bent section, but in the heat pipe 1, the shape in the longitudinal direction is a shape including a bent section.

Specifically, the shape of the container 10 of the heat pipe 1 in the longitudinal direction is a substantially L shape including one bent section 15 and two straight sections that are continuous through the bent section 15. The two straight sections are a straight section 16 including the one end portion 11, and a straight section 17 including the other end portion 13. Thus, the heat pipe 1 is an L-shaped heat pipe.

The wick structural body 20 extends from the one end portion 11 to the other end portion 13 of the container 10 along the longitudinal direction of the container 10. For example, the heat pipe 1 functions as an evaporation section when a heat-generating body 100 is thermally connected to the straight section 16 including the one end portion 11, and functions as a condensation section when a heat exchange means (not illustrated in FIGS. 1 and 2) is thermally connected to the straight section 17 including the other end portion 13. From the above description, the wick structural body 20 extends along a heat transfer direction of the heat pipe 1.

The wick structural body 20 is, for example, a fine groove provided on the inner surface of the container 10, or a porous body provided on the inner surface of the container 10. The wick structural body 20 may be only a fine groove provided on the inner surface of the container 10, may be only a porous body provided on the inner surface of the container 10, or may be a composite body including a fine groove provided on the inner surface of the container 10 and a porous body formed on the fine groove. The porous body is, for example, a sintered body made of sintered metal powder such as copper powder. The shape of the porous body is, for example, a porous body layer formed in a layered shape on the inner peripheral surface of the container 10.

As illustrated in FIG. 2, in the heat pipe 1, the wick structural body 20 is a plurality of fine grooves 21, 21, 21, . . . provided on the inner surface of the container 10. The plurality of fine grooves 21, 21, 21, . . . extend from the one end portion 11 to the other end portion 13 along the longitudinal direction of the container 10. The plurality of fine grooves 21, 21, 21, . . . are formed on the entire inner peripheral surface of the container 10. In the heat pipe 1, no wick structural body of a porous body is provided, and the plurality of fine grooves 21, 21, 21, . . . are exposed to the hollow section 18 of the container 10. Since the wick structural body 20 is the plurality of fine grooves 21, 21, 21, . . . provided on the inner surface of the container 10, it is possible to reliably achieve a flow path through which the working fluid 30 in the vapor phase circulates.

The shape of the fine groove 21 in the direction orthogonal to the longitudinal direction of the container 10 is not particularly limited but is, for example, the first shape of a plurality of fine grooves 21-1, 21-1, 21-1, . . . the shape of which in the direction orthogonal to the longitudinal direction of the container 10 is a rectangular shape as illustrated in FIGS. 2 and 3, the second shape of a plurality of fine grooves 21-2, 21-2, 21-2, . . . the shape of which in the direction orthogonal to the longitudinal direction of the container 10 is a triangular shape as illustrated in FIG. 4, or the third shape of a plurality of fine grooves 21-3, 21-3, 21-3, . . . the shape of which in the direction orthogonal to the longitudinal direction of the container 10 is a trapezoidal shape as illustrated in FIG. 5.

Since the shape of the fine groove 21 in the direction orthogonal to the longitudinal direction of the container 10 is a rectangular shape, a triangular shape, or a trapezoidal shape, it is possible to reliably achieve the circular current characteristics of the working fluid in the liquid phase.

In the case of the fine grooves 21-1 that are rectangular, the depth (H) of each fine groove 21-1 is not particularly limited but preferably equal to or larger than 0.15 mm and equal to or smaller than 0.50 mm, further preferably equal to or larger than 0.30 mm and equal to or smaller than 0.50 mm, and particularly preferably equal to or larger than 0.35 mm and equal to or smaller than 0.45 mm from the standpoint that formation of the fine grooves 21-1 is easy, the circular current characteristics of the working fluid 30 containing hydrofluoroolefin in the liquid phase improve, and the heat transfer characteristics of the heat pipe 1 further improve. The width (W) of each fine groove 21-1 is not particularly limited but is preferably equal to or larger than 0.15 mm and equal to or smaller than 0.60 mm, further preferably equal to or larger than 0.15 mm and equal to or smaller than 0.40 mm, and particularly preferably equal to or larger than 0.15 mm and equal to or smaller than 0.35 mm from the standpoint that formation of the fine grooves 21-1 is easy, the circular current characteristics of the working fluid 30 containing hydrofluoroolefin in the liquid phase improve, and the heat transfer characteristics of the heat pipe 1 further improve.

In the case of the fine grooves 21-2 that are triangular, the depth (H) of each fine groove 21-2 is not particularly limited but is preferably equal to or larger than 0.15 mm and equal to or smaller than 0.50 mm, further preferably equal to or larger than 0.30 mm and equal to or smaller than 0.50 mm, and particularly preferably equal to or larger than 0.35 mm and equal to or smaller than 0.45 mm from the standpoint that formation of the fine grooves 21-2 is easy, the circular current characteristics of the working fluid 30 containing hydrofluoroolefin in the liquid phase improve, and the heat transfer characteristics of the heat pipe 1 further improve. The width (W) of each fine groove 21-2 at a site ((½)H) of ½ of the depth (H) is not particularly limited but is preferably equal to or larger than 0.15 mm and equal to or smaller than 1.00 mm, further preferably equal to or larger than 0.15 mm and equal to or smaller than 0.90 mm, and particularly preferably equal to or larger than 0.15 mm and equal to or smaller than 0.80 mm from the standpoint that formation of the fine grooves 21-2 is easy, the circular current characteristics of the working fluid 30 containing hydrofluoroolefin in the liquid phase improve, and the heat transfer characteristics of the heat pipe 1 further improve.

In the case of the fine grooves 21-3 that are trapezoidal, the depth (H) of each fine groove 21-3 is not particularly limited but is preferably equal to or larger than 0.15 mm and equal to or smaller than 0.50 mm, further preferably equal to or larger than 0.30 mm and equal to or smaller than 0.50 mm, and particularly preferably equal to or larger than 0.35 mm and equal to or smaller than 0.45 mm from the standpoint that formation of the fine grooves 21-3 is easy, the circular current characteristics of the working fluid 30 containing hydrofluoroolefin in the liquid phase improve, and the heat transfer characteristics of the heat pipe 1 further improve. The average value of the width (W) of each fine groove 21-3 is not particularly limited but is preferably equal to or smaller than 0.05 mm 1.00 mm, further preferably equal to or larger than 0.15 mm and equal to or smaller than 0.90 mm, and particularly preferably equal to or larger than 0.15 mm and equal to or smaller than 0.80 mm from the standpoint that formation of the fine grooves 21-3 is easy, the circular current characteristics of the working fluid 30 containing hydrofluoroolefin in the liquid phase improve, and the heat transfer characteristics of the heat pipe 1 further improve.

The sectional shape of the container 10 in the direction orthogonal to the longitudinal direction is not particularly limited but is a substantially circular shape for the container 10 of the heat pipe 1 as illustrated in FIGS. 2 to 5. The thickness of the container 10 is not particularly limited but is, for example, equal to or larger than 0.1 mm and equal to or smaller than 0.7 mm. The inner diameter of the container 10, in other words, the diameter of the hollow section 18 is not particularly limited but is, for example, equal to or larger than 3.0 mm and equal to or smaller than 32 mm.

In the heat pipe 1, the shape of the container 10 in the longitudinal direction is a shape including a straight section and a bent section, and specifically, is a substantially L shape with the one bent section 15 and the straight sections 16 and 17 formed through the bent section 15, the straight section 16 including the one end portion 11, the straight section 17 including the other end portion 13. In the heat pipe 1 having a substantially L shape, the encapsulated amount of the working fluid 30 is not particularly limited but is preferably an encapsulated amount with which the working fluid 30 has a cross-sectional area that is 40% or more of the cross-sectional area of the hollow section 18 that is the internal space of the straight section 16 in at least one section among sections of the straight section 16 in the direction orthogonal to the longitudinal direction when the longitudinal direction of the straight section 16 is a direction orthogonal to the direction of gravity from the standpoint to provide excellent heat transfer characteristics to the heat pipe 1, is further preferably an encapsulated amount with which the working fluid 30 has a cross-sectional area that is 50% or more of the cross-sectional area of the hollow section 18 from the standpoint that the heat transfer characteristics of the heat pipe 1 further improve, and is particularly preferably an encapsulated amount with which the working fluid 30 has a cross-sectional area that is 55% or more of the cross-sectional area of the hollow section 18. Note that, as described later, for example, the heat-generating body 100 is thermally connected to the straight section 16.

A site to which the heat-generating body 100 that is a cooling target of the heat pipe 1 is thermally connected can be selected as appropriate in accordance with usage conditions and the like of the heat pipe 1. For example, the heat-generating body 100 may be thermally connected to the straight section 17 in place of the straight section 16 of the heat pipe 1.

The material of the container 10 is, for example, copper (for example, oxygen-free copper or phosphor deoxidized copper), a copper alloy, aluminum, an aluminum alloy, stainless steel, titanium, or a titanium alloy.

The mechanism of heat transfer of the heat pipe 1 according to the first example embodiment of the present disclosure will be described next. In the heat pipe 1, for example, the straight section 16 including the one end portion 11 functions as an evaporation section (heat-receiving section) by thermally connecting the heat-generating body 100 to the straight section 16 including the one end portion 11, and the straight section 17 including the other end portion 13 functions as a condensation section (heat-releasing section) by thermally connecting a heat exchange means to the straight section 17 including the other end portion 13. When the heat pipe 1 receives heat from the heat-generating body 100 at the evaporation section, the working fluid 30 undergoes a phase change from the liquid phase to the vapor phase. As the working fluid 30 having undergone the phase change to the vapor phase flows through the hollow section 18 in the longitudinal direction of the container 10 from the evaporation section to the condensation section (in the heat pipe 1, from the one end portion 11 to the other end portion 13), the heat from the heat-generating body 100 is transferred from the evaporation section to the condensation section. The heat from the heat-generating body 100, which is transferred from the evaporation section to the condensation section is discharged as latent heat as the working fluid 30 in the vapor phase undergoes a phase change to the liquid phase at the condensation section provided with the heat exchange means. The latent heat discharged at the condensation section is discharged from the condensation section to the external environment of the heat pipe 1 by the heat exchange means provided at the condensation section. The working fluid 30 having undergone the phase change to the liquid phase at the condensation section is returned from the condensation section to the evaporation section by capillary force of the wick structural body 20.

The temperature of the operating environment of the heat pipe 1 with the working fluid 30 containing hydrofluoroolefin is, for example, equal to or higher than-50° C. and equal to or lower than 90° C. Note that, as necessary, a heat-receiving block may be further thermally connected to the evaporation section that is a partial region of the container 10. In a case where a heat-receiving block is thermally connected to the evaporation section of the container 10, heat of the heat-generating body 100 is transferred to the evaporation section through the heat-receiving block. The method of thermally connecting the heat-receiving block to the container 10 is not particularly limited but is, for example, a method of fitting and soldering the evaporation section of the container 10 to a recessed part formed in the heat-receiving block.

In the heat pipe 1 according to the first example embodiment of the present disclosure, since the working fluid 30 contains hydrofluoroolefin, it is possible to prevent freezing of the working fluid 30 and exhibit excellent circulation characteristics even in a low-temperature operating environment while reducing impact on environment. Moreover, since the heat pipe 1 according to the first example embodiment includes: the container 10 including the one end portion 11 and the other end portion 13 opposite the one end portion 11, the end face 12 of the one end portion 11 and the end face 14 of the other end portion 13 being sealed; the wick structural body 20 provided inside the container 10; and the working fluid 30 encapsulated inside the container 10, and the wick structural body 20 includes the fine groove 21 provided on the inner surface of the container 10 and/or the porous body provided on the inner surface of the container 10, the heat pipe is not a loop type and circular current of the working fluid in the liquid phase due to the action of gravity is not essential, and thus space saving and improvement of flexibility of installation are possible.

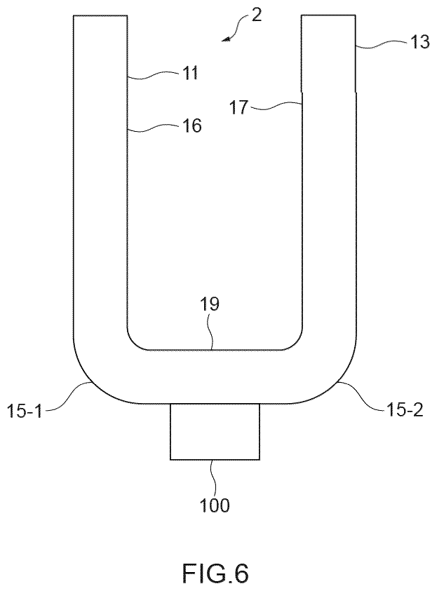

A heat pipe according to a second example embodiment of the present disclosure will be described next. Note that the heat pipe according to the second example embodiment has main constituent components in common with the heat pipe according to the first example embodiment, and thus the same constituent components will be described by using the same reference signs. Note that FIG. 6 is an explanatory diagram illustrating an overview of the heat pipe according to the second example embodiment of the present disclosure in the longitudinal direction.

The shape of the heat pipe 1 according to the first example embodiment of the present disclosure in the longitudinal direction is a substantially L shape including the one bent section 15 and the two straight sections 16 and 17 that are continuous through the bent section 15, but the shape of a heat pipe 2 according to the second example embodiment in the longitudinal direction is a substantially U shape instead as illustrated in FIG. 6. The container 10 is disposed such that the straight section 16 including the one end portion 11 and the straight section 17 including the other end portion 13 face each other, and a central part 19 that is straight connects the straight section 16 including the one end portion 11 and the straight section 17 including the other end portion 13. A bent section 15-1 is provided between the straight section 16 including the one end portion 11 and the central part 19, and a bent section 15-2 is provided between the straight section 17 including the other end portion 13 and the central part 19, and accordingly, the shape of the container 10 in the longitudinal direction is a substantially U shape. Thus, the heat pipe 2 is a substantially U-shaped heat pipe including two bent sections in the longitudinal direction.

In this manner, in the heat pipe of the present disclosure, the shape of the container 10 in the longitudinal direction is not particularly limited. Note that the configuration of a section of the heat pipe 2 in the direction orthogonal to the longitudinal direction is the same as the configuration of the section of the heat pipe 1 according to the first example embodiment in the direction orthogonal to the longitudinal direction, which is illustrated in FIG. 2.

The mechanism of heat transfer of the heat pipe 2 that is substantially U-shaped will be described next. In the heat pipe 2, for example, the heat-generating body 100 is thermally connected to the central part 19, and the straight section 16 including the one end portion 11 and the straight section 17 including the other end portion 13 function as condensation sections (heat-releasing sections) by thermally connecting heat exchange means to the straight section 16 including the one end portion 11 and the straight section 17 including the other end portion 13. When the heat pipe 2 receives heat from the heat-generating body 100 thermally connected to the central part 19, the central part 19 functions as an evaporation section and the working fluid 30 containing hydrofluoroolefin undergoes a phase change from the liquid phase to the vapor phase at the evaporation section. As the working fluid 30 having undergone the phase change to the vapor phase flows through the hollow section 18 the longitudinal direction of the container 10 from the evaporation section positioned at the central part 19 to the condensation sections positioned at the straight section 16 including the one end portion 11 and the straight section 17 including the other end portion 13, the heat from the heat-generating body 100 is transferred from the evaporation section to the condensation sections. The heat from the heat-generating body 100, which is transferred from the evaporation section to the condensation section is discharged as latent heat as the working fluid 30 in the vapor phase undergoes a phase change to the liquid phase at the condensation sections provided with the heat exchange means. The latent heat discharged at the condensation sections is discharged from the condensation sections to the external environment of the heat pipe 2 by the heat exchange means provided at the condensation sections. The working fluid 30 having undergone the phase change to the liquid phase at the condensation sections is returned from the condensation sections to the evaporation section by capillary force of the wick structural body 20.

In the heat pipe 2 as well, since the working fluid 30 contains hydrofluoroolefin, it is possible to prevent freezing of the working fluid 30 and exhibit excellent circulation characteristics even in a low-temperature operating environment while reducing impact on environment. Moreover, since the heat pipe 2 as well includes: the container 10 including the one end portion 11 and the other end portion 13 facing the one end portion 11, the end face 12 of the one end portion 11 and the end face 14 of the other end portion 13 being sealed; the wick structural body 20 provided inside the container 10; and the working fluid 30 encapsulated inside the container 10, and the wick structural body 20 includes the fine groove 21 provided on the inner surface of the container 10 and/or the porous body provided on the inner surface of the container 10, the heat pipe is not a loop type and circular current of the working fluid in the liquid phase due to the action of gravity is not essential, and thus space saving and improvement of flexibility of installation are possible.

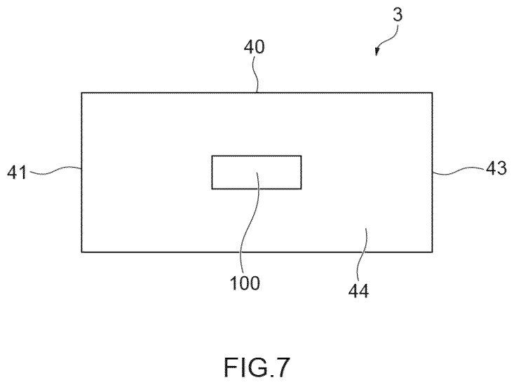

A heat pipe according to a third example embodiment of the present disclosure will be described next. Note that the heat pipe according to the third example embodiment has main constituent components in common with the heat pipes according to the first and second example embodiments, and thus the same constituent components will be described by using the same reference signs. Note that FIG. 7 is an explanatory diagram illustrating an aspect of the heat pipe according to the third example embodiment of the present disclosure in plan view.

In the heat pipes 1 and 2 according to the first and second example embodiments of the present disclosure, the container 10 is a tubular body and the sectional shape of the container 10 in the direction orthogonal to the longitudinal direction is a substantially circular shape, but in a heat pipe 3 according to the third example embodiment, a container 40 is planar instead as illustrated in FIG. 7. From the above description, the heat pipe 3 is a vapor chamber.

In the heat pipe 3, a working fluid containing hydrofluoroolefin is encapsulated in the container 40 that is planar, and a wick structural body is provided inside the container 40 that is planar.

The shape of the container 40 in plan view is not particularly limited but is a rectangular shape in the heat pipe 3 for convenience of description. The dimensions of the container 40 in plan view are not particularly limited but are, for example, equal to or larger than 100 mm and equal to or smaller than 500 mm on the long side and equal to or larger than 50 mm and equal to or smaller than 400 mm on the short side in a case of a rectangular shape. In a case of a square shape, the length of one side is, for example, equal to or larger than 100 mm and equal to or smaller than 500 mm. In addition, the thickness of the internal space of the container 40 is, for example, equal to or larger than 1.0 mm and equal to or smaller than 5.0 mm. In the container 40 of the heat pipe 3 that is rectangular in plan view, one short side 41 is one end portion, and a short side 43 opposite the short side 41 that is the one end portion is the other end portion.

The mechanism of heat transfer of the heat pipe 3 according to the third example embodiment of the present disclosure will be described next. In the container 40, the heat-generating body 100 is thermally connected to an outer surface central part of one main surface 44, and the outer surface central part of the one main surface 44 functions as a heat-receiving section. When the heat pipe 3 receives heat from the heat-generating body 100 at the heat-receiving section, a working fluid in the liquid phase, which is encapsulated in a hollow section that is the internal space of the container 40 undergoes a phase change from the liquid phase to the vapor phase at the heat-receiving section, and the working fluid in the vapor phase, which has undergone the phase change circulates through the hollow section and diffuses across the entire hollow section from the heat-receiving section of the heat pipe 3. The working fluid in the vapor phase, which has diffused across the entire hollow section from the heat-receiving section releases latent heat and undergoes a phase change from the vapor phase to the liquid phase. At this time, the discharged latent heat is discharged from the entire container 40 to the external environment of the heat pipe 3. The working fluid having undergone the phase change from the vapor phase to the liquid phase is returned from the entire hollow section to the heat-receiving section by capillary force of the wick structural body inside the container 40.

In the heat pipe 3 as well, since the working fluid contains hydrofluoroolefin, it is possible to prevent freezing of the working fluid and exhibit excellent circulation characteristics even in a low-temperature operating environment while reducing impact on environment. Moreover, since the heat pipe 3 as well includes: the container 40 including the short side 41 that is one end portion and the short side 43 that is the other end portion facing the short side 41, an end face of the one end portion and an end face of the other end portion being sealed; the wick structural body provided inside the container 40; and the working fluid encapsulated inside the container 40, and the wick structural body includes a fine groove provided on the inner surface of the container 40 and/or a porous body provided on the inner surface of the container 40, the heat pipe is not a loop type and circular current of the working fluid in the liquid phase due to the action of gravity is not essential, and thus space saving and improvement of flexibility of installation are possible.

A heat sink using the heat pipe of the present disclosure will be described next. The heat sink using the heat pipe of the present disclosure includes the heat pipe of the present disclosure and heat-releasing fins thermally connected to a first region that is a partial region of the container of the heat pipe. The heat pipe is a heat transfer section of the heat sink.

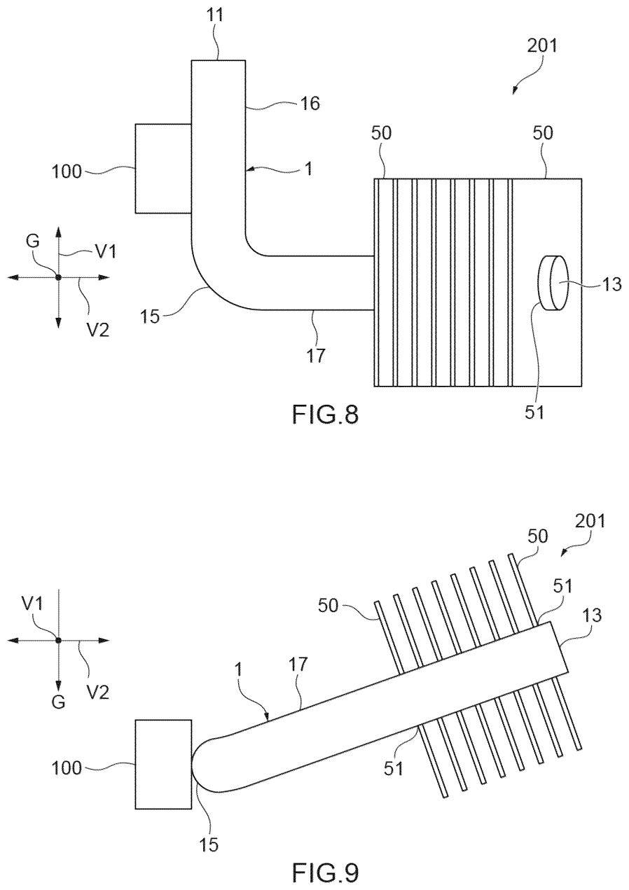

First, a heat sink according to a first example embodiment of the present disclosure will be described with reference to the accompanying drawings. Note that FIG. 8 is a plan view illustrating an overview of the heat sink according to the first example embodiment of the present disclosure. FIG. 9 is a side view illustrating an overview of the heat sink according to the first example embodiment of the present disclosure.

As illustrated in FIGS. 8 and 9, in a heat sink 201 according to the first example embodiment of the present disclosure, the heat pipe 1 according to the first example embodiment, in other words, an L-shaped heat pipe is used as the heat transfer section. The shape of the heat pipe 1 in the longitudinal direction is a substantially L shape including the one bent section 15 and two straight sections that are continuous through the bent section 15. The two straight sections are the straight section 16 including the one end portion 11, and the straight section 17 including the other end portion 13.

The heat-generating body 100 is thermally connected to the straight section 16 including the one end portion 11 and the straight section 16 functions as an evaporation section (heat-receiving section). In addition, a plurality of heat-releasing fins 50, 50, 50, . . . are thermally connected as heat exchange means to the straight section 17 including the other end portion 13 and the straight section 17 functions as a condensation section (heat-releasing section). Each heat-releasing fin 50 is a thin-plate metal member. A through-hole 51 is formed in the thickness direction of the heat-releasing fins 50, and the heat-releasing fins 50 are thermally connected to the straight section 17 by fitting and inserting the straight section 17 of the heat pipe 1 into the through-hole 51.

In the heat sink 201, the straight section 16 to which the heat-generating body 100 is thermally connected extends in a first orthogonal direction V1 (front-back direction) that is a first direction orthogonal to a gravity direction G. The straight section 17 to which the heat-releasing fins 50 are thermally connected extends in a direction that slopes upward at a predetermined angle (for example, 10° approximately) with respect to a second orthogonal direction V2 (right-left direction) that is a direction orthogonal to the gravity direction G and the first orthogonal direction V1. The bent section 15 is at the same position in the gravity direction G as the straight section 16 to which the heat-generating body 100 is thermally connected.

In the heat sink 201, a heat-receiving block is omitted for convenience of description, but as in a heat sink according to a sixth example embodiment to be described later, a heat-receiving block extending along the gravity direction G may be further thermally connected to a region of the straight section 16 including the one end portion 11 in the heat pipe 1. The method of thermally connecting the heat-receiving block to the heat pipe 1 is not particularly limited but is, for example, a method of fitting and soldering the straight section 16 of the heat pipe 1 to a recessed part formed in the heat-receiving block. The heat-generating body 100 is thermally connected to the outer surface of the heat-receiving block, and heat of the heat-generating body 100 is transferred to the straight section 16 of the heat pipe 1 through the heat-receiving block.

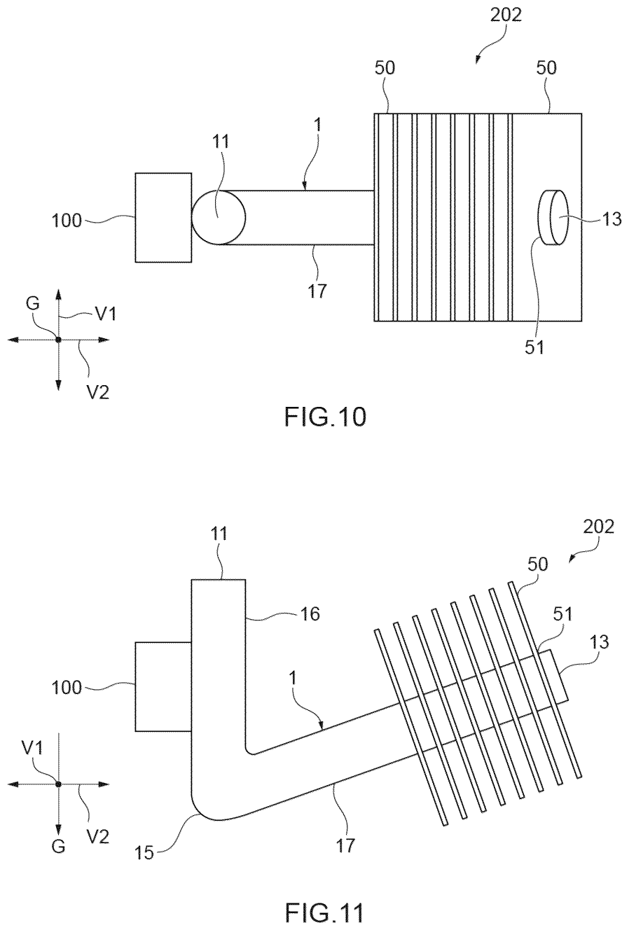

A heat sink according to a second example embodiment of the present disclosure will be described next with reference to the accompanying drawings. Note that FIG. 10 is a plan view illustrating an overview of the heat sink according to the second example embodiment of the present disclosure. FIG. 11 is a side view illustrating an overview of the heat sink according to the second example embodiment of the present disclosure.

As illustrated in FIGS. 10 and 11, in a heat sink 202 according to the second example embodiment of the present disclosure, the heat pipe 1 according to the first example embodiment, in other words, an L-shaped heat pipe is used as the heat transfer section. The shape of the heat pipe 1 in the longitudinal direction is a substantially L shape including the one bent section 15 and two straight sections that are continuous through the bent section 15. The two straight sections are the straight section 16 including the one end portion 11, and the straight section 17 including the other end portion 13.

The heat-generating body 100 is thermally connected to the straight section 16 including the one end portion 11 and the straight section 16 functions as an evaporation section (heat-receiving section). In addition, the plurality of heat-releasing fins 50, 50, 50, . . . are thermally connected as heat exchange means to the straight section 17 including the other end portion 13 and the straight section 17 functions as a condensation section (heat-releasing section). Each heat-releasing fin 50 is a thin-plate metal member. The through-hole 51 is formed in the thickness direction of the heat-releasing fins 50, and the heat-releasing fins 50 are thermally connected to the straight section 17 by fitting and inserting the straight section 17 of the heat pipe 1 into the through-hole 51.

In the heat sink 202, the straight section 16 to which the heat-generating body 100 is thermally connected extends in the gravity direction G. The straight section 17 to which the heat-releasing fins 50 are thermally connected extends in a direction that slopes upward at a predetermined angle (for example, 10° approximately) with respect to the second orthogonal direction V2 that is a direction orthogonal to the gravity direction G and the first orthogonal direction V1. The bent section 15 is positioned on the lower side in the gravity direction G with respect to the straight section 16 to which the heat-generating body 100 is thermally connected.

In the heat sink 202, a heat-receiving block is omitted for convenience of description, but as in the heat sink according to the sixth example embodiment to be described later, a heat-receiving block extending along the gravity direction G may be further thermally connected to a region of the straight section 16 including the one end portion 11 in the heat pipe 1. The method of thermally connecting the heat-receiving block to the heat pipe 1 is not particularly limited but is, for example, a method of fitting and soldering the straight section 16 of the heat pipe 1 to a recessed part formed in the heat-receiving block. The heat-generating body 100 is thermally connected to the outer surface of the heat pipe 1, and heat of the heat-generating body 100 is transferred to the straight section 16 of the heat pipe 1 through the heat-receiving block.

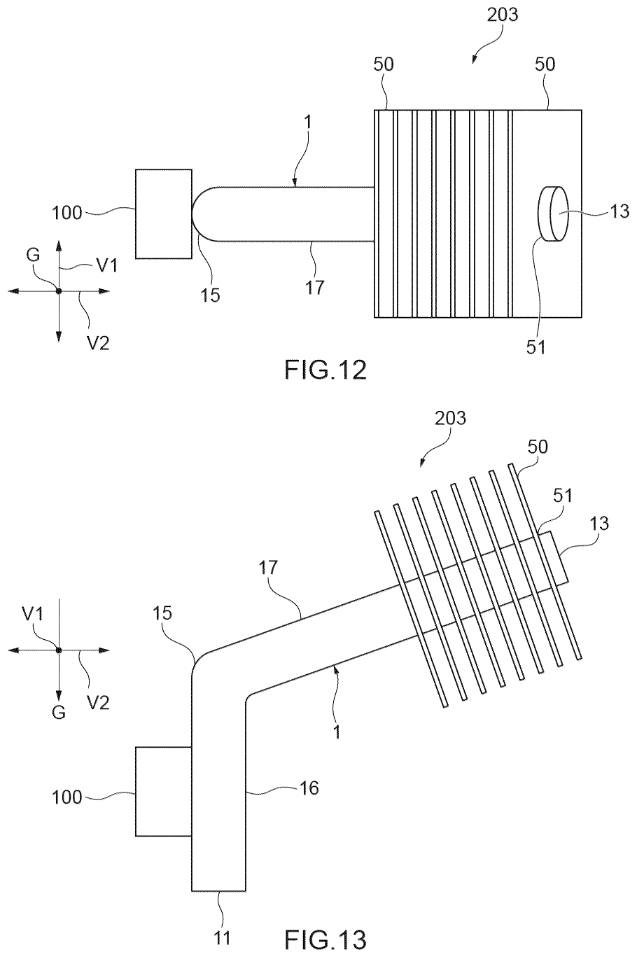

A heat sink according to a third example embodiment of the present disclosure will be described next with reference to the accompanying drawings. Note that FIG. 12 is a plan view illustrating an overview of the heat sink according to the third example embodiment of the present disclosure. FIG. 13 is a side view illustrating an overview of the heat sink according to the third example embodiment of the present disclosure.

As illustrated in FIGS. 12 and 13, in a heat sink 203 according to the third example embodiment of the present disclosure, the heat pipe 1 according to the first example embodiment, in other words, an L-shaped heat pipe is used as the heat transfer section. The shape of the heat pipe 1 in the longitudinal direction is a substantially L shape including the one bent section 15 and two straight sections that are continuous through the bent section 15. The two straight sections are the straight section 16 including the one end portion 11, and the straight section 17 including the other end portion 13.

The heat-generating body 100 is thermally connected to the straight section 16 including the one end portion 11 and the straight section 16 functions as an evaporation section (heat-receiving section). In addition, the plurality of heat-releasing fins 50, 50, 50, . . . are thermally connected as heat exchange means to the straight section 17 including the other end portion 13 and the straight section 17 functions as a condensation section (heat-releasing section). Each heat-releasing fin 50 is a thin-plate metal member. The through-hole 51 is formed in the thickness direction of the heat-releasing fins 50, and the heat-releasing fins 50 are thermally connected to the straight section 17 by fitting and inserting the straight section 17 of the heat pipe 1 into the through-hole 51.

In the heat sink 203, the straight section 16 to which the heat-generating body 100 is thermally connected extends in the gravity direction G. The straight section 17 to which the heat-releasing fins 50 are thermally connected extends in a direction that slopes upward at a predetermined angle (for example, 10° approximately) with respect to the second orthogonal direction V2 that is a direction orthogonal to the gravity direction G and the first orthogonal direction V1. The bent section 15 is positioned on the upper side in the gravity direction G with respect to the straight section 16 to which the heat-generating body 100 is thermally connected.

In the heat sink 203, a heat-receiving block is omitted for convenience of description, but as in the heat sink according to the sixth example embodiment to be described later, a heat-receiving block extending along the gravity direction G may be further thermally connected to a region of the straight section 16 including the one end portion 11 in the heat pipe 1. The method of thermally connecting the heat-receiving block to the heat pipe 1 is not particularly limited but is, for example, a method of fitting and soldering the straight section 16 of the heat pipe 1 to a recessed part formed in the heat-receiving block. The heat-generating body 100 is thermally connected to the outer surface of the heat-receiving block, and heat of the heat-generating body 100 is transferred to the straight section 16 of the heat pipe 1 through the heat-receiving block.

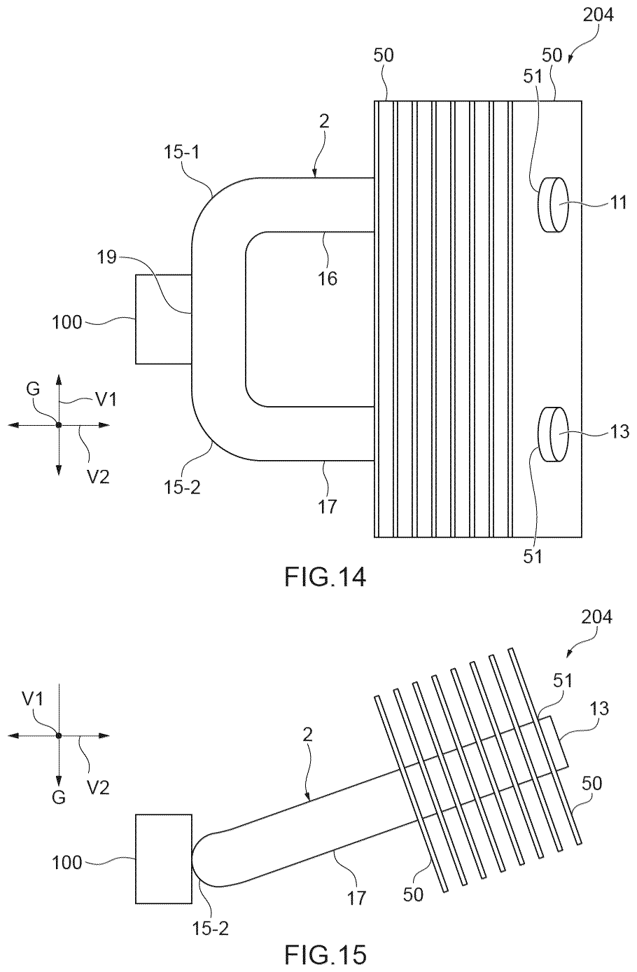

A heat sink according to a fourth example embodiment of the present disclosure will be described next with reference to the accompanying drawings. Note that FIG. 14 is a plan view illustrating an overview of the heat sink according to the fourth example embodiment of the present disclosure. FIG. 15 is a side view illustrating an overview of the heat sink according to the fourth example embodiment of the present disclosure.

As illustrated in FIGS. 14 and 15, in a heat sink 204 according to the fourth example embodiment of the present disclosure, the heat pipe 2 according to the second example embodiment, in other words, a substantially U-shaped heat pipe is used as the heat transfer section. The shape of the heat pipe 2 in the longitudinal direction is disposed such that the straight section 16 including the one end portion 11 and the straight section 17 including the other end portion 13 face each other, and the central part 19 that is straight connects the straight section 16 including the one end portion 11 and the straight section 17 including the other end portion 13. The bent section 15-1 is provided between the straight section 16 including the one end portion 11 and the central part 19, and the bent section 15-2 is provided between the straight section 17 including the other end portion 13 and the central part 19.

The heat-generating body 100 is thermally connected to the central part 19 and the central part 19 functions as an evaporation section (heat-receiving section). In addition, the plurality of heat-releasing fins 50, 50, 50, . . . are thermally connected as heat exchange means to the straight section 16 including the one end portion 11 and the straight section 17 including the other end portion 13 and the straight section 16 and the straight section 17 function as a condensation section (heat-releasing section). Each heat-releasing fin 50 is a thin-plate metal member. Two through-holes 51 are formed in the thickness direction of the heat-releasing fins 50, and the heat-releasing fins 50 are thermally connected to the straight section 16 and the straight section 17 by fitting and inserting the straight section 16 of the heat pipe 2 to one of the through-holes 51, and the straight section 17 of the heat pipe 2 to the other through-hole 51.

In the heat sink 204, the central part 19 to which the heat-generating body 100 is thermally connected extends in the first orthogonal direction V1 (front-back direction) that is a first direction orthogonal to the gravity direction G. The straight section 16 and the straight section 17 to which the heat-releasing fins 50 are thermally connected extend in a direction that slopes upward at a predetermined angle (for example, 10° approximately) with respect to the second orthogonal direction V2 (right-left direction) that is a direction orthogonal to the gravity direction G and the first orthogonal direction V1. The bent section 15-1 and the bent section 15-2 at the same position in the gravity direction G as the central part 19 to which the heat-generating body 100 is thermally connected.

In the heat sink 204, a heat-receiving block is omitted for convenience of description, but as in the heat sink according to the sixth example embodiment to be described later, a heat-receiving block extending along the gravity direction G may be further thermally connected to a region of the central part 19 that is straight in the heat pipe 2. The method of thermally connecting the heat-receiving block to the heat pipe 2 is not particularly limited but is, for example, a method of fitting and soldering the central part 19 of the heat pipe 2 to a recessed part formed in the heat-receiving block. The heat-generating body 100 is thermally connected to the outer surface of the heat-receiving block, and heat of the heat-generating body 100 is transferred to the central part 19 of the heat pipe 2 through the heat-receiving block.

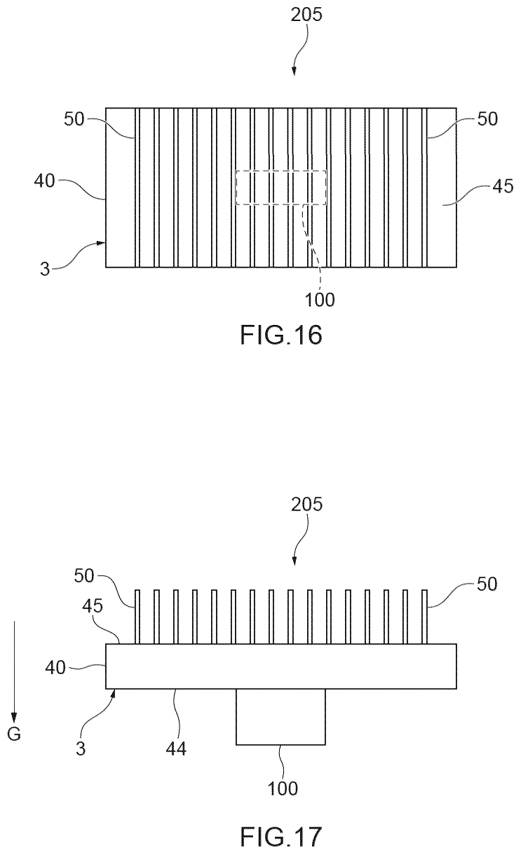

A heat sink according to a fifth example embodiment of the present disclosure will be described next with reference to the accompanying drawings. Note that FIG. 16 is a plan view illustrating an overview of the heat sink according to the fifth example embodiment of the present disclosure. FIG. 17 is a side view illustrating an overview of the heat sink according to the fifth example embodiment of the present disclosure.

As illustrated in FIGS. 16 and 17, in a heat sink 205 according to the fifth example embodiment of the present disclosure, the heat pipe 3 according to the third example embodiment, in other words, a vapor chamber that is a planar heat pipe is used as the heat transfer section.

In the container 40 that is planar, the heat-generating body 100 is thermally connected to the outer surface central part of the one main surface 44, and the outer surface central part of the one main surface 44 functions as a heat-receiving section. The plurality of heat-releasing fins 50, 50, 50, . . . are thermally connected to another main surface 45 opposite the one main surface 44. Each heat-releasing fin 50 is a thin-plate metal member. The heat-releasing fins 50 are erected on the other main surface 45 such that the heat-releasing fins 50 are thermally connected to the other main surface 45.

In the heat sink 205, the one main surface 44 and the other main surface 45 extend in a direction orthogonal to the gravity direction G.

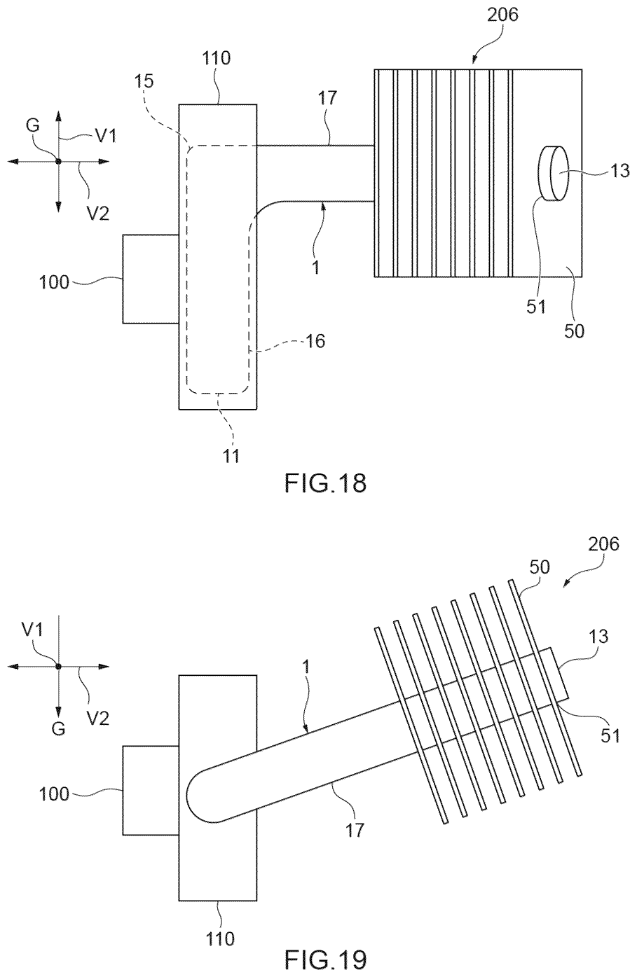

The heat sink according to the sixth example embodiment of the present disclosure will be described next with reference to the accompanying drawings. Note that FIG. 18 is a plan view illustrating an overview of the heat sink according to the sixth example embodiment of the present disclosure. FIG. 19 is a side view illustrating an overview of the heat sink according to the sixth example embodiment of the present disclosure.

As illustrated in FIGS. 18 and 19, in a heat sink 206 according to the sixth example embodiment, the heat pipe 1 according to the first example embodiment, in other words, an L-shaped heat pipe is used as the heat transfer section. The shape of the heat pipe 1 in the longitudinal direction is a substantially L shape including the one bent section 15 and two straight sections that are continuous through the bent section 15. The two straight sections are the straight section 16 including the one end portion 11, and the straight section 17 including the other end portion 13.

In the heat sink 206, a heat-receiving block 110 is further thermally connected to a region of the straight section 16 including the one end portion 11 of the container 10. The method of thermally connecting the heat-receiving block 110 to the container 10 is not particularly limited but is, for example, a method of fitting and soldering the straight section 16 of the container 10 to a recessed part formed in the heat-receiving block 110. The heat-generating body 100 is thermally connected to the outer surface of the heat-receiving block 110, and heat of the heat-generating body 100 is transferred to the straight section 16 of the container 10 through the heat-receiving block 110.

The heat-generating body 100 is thermally connected to the straight section 16 including the one end portion 11 through the heat-receiving block 110 and the straight section 16 functions as an evaporation section (heat-receiving section). In addition, the plurality of heat-releasing fins 50, 50, 50, . . . are thermally connected as heat exchange means to the straight section 17 including the other end portion 13 and the straight section 17 functions as a condensation section (heat-releasing section). Each heat-releasing fin 50 is a thin-plate metal member. The through-hole 51 is formed in the thickness direction of the heat-releasing fins 50, and the heat-releasing fins 50 are thermally connected to the straight section 17 by fitting and inserting the straight section 17 of the heat pipe 1 into the through-hole 51.

In the heat sink 206, the straight section 16 to which the heat-generating body 100 is thermally connected through the heat-receiving block 110 extends in the first orthogonal direction V1 (front-back direction) that is a first direction orthogonal to the gravity direction G. The straight section 17 to which the heat-releasing fins 50 are thermally connected extends in a direction that slopes upward at a predetermined angle (for example, 10° approximately) with respect to the second orthogonal direction V2 (right-left direction) that is a direction orthogonal to the gravity direction G and the first orthogonal direction V1. The bent section 15 is at the same position in the gravity direction G as the straight section 16 to which the heat-generating body 100 is thermally connected through the heat-receiving block 110.

The temperature of the operating environment of the heat sinks according to the above-described example embodiments is, for example, equal to or higher than −50° C. and equal to or lower than 90° C.

Since the heat sinks 201 to 206 according to the above-described example embodiments include the heat pipes 1 to 3 and the heat-releasing fins 50 thermally connected to partial regions of the containers 10 and 40 of the heat pipes 1 to 3, it is possible to prevent freezing of the working fluid 30 of the heat pipes 1 to 3 and exhibit excellent circulation characteristics of the working fluid 30 even in a low-temperature operating environment, and space saving and improvement of flexibility of installation are possible.

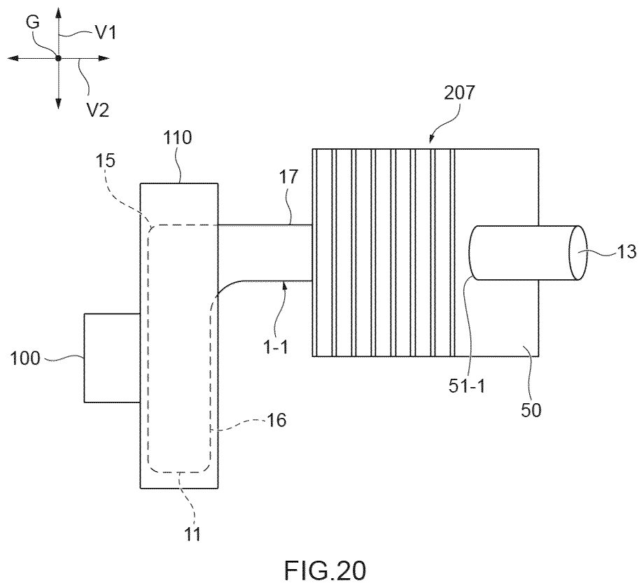

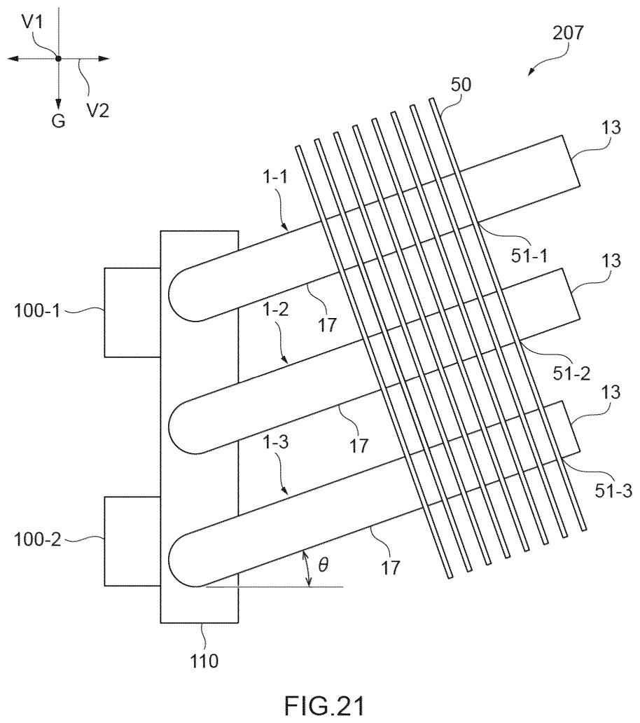

A heat sink according to a seventh example embodiment of the present disclosure will be described next with reference to the accompanying drawings. Note that FIG. 20 is a plan view illustrating an overview of the heat sink according to the seventh example embodiment of the present disclosure. FIG. 21 is a side view illustrating an overview of the heat sink according to the seventh example embodiment of the present disclosure.

As illustrated in FIGS. 20 and 21, in a heat sink 207 according to the seventh example embodiment, the heat pipe according to the first example embodiment, in other words, a plurality of L-shaped heat pipes (in this example, three heat pipes 1-1, 1-2, and 1-3) are used as the heat transfer section. The shapes of the heat pipes 1-1, 1-2, and 1-3 in the longitudinal direction are each a substantially L shape including the one bent section 15 and two straight sections that are continuous through the bent section 15. The two straight sections are the straight section 16 including the one end portion 11, and the straight section 17 including the other end portion 13.

In the heat sink 207, the heat-receiving block 110 is further thermally connected to the region of the straight section 16 including the one end portion 11 of the container 10 in each of the heat pipes 1-1, 1-2, and 1-3. The method of thermally connecting the heat-receiving block 110 to the container 10 is not particularly limited but is, for example, a method of fitting and soldering the straight section 16 of the container 10 to a recessed part formed in the heat-receiving block 110. Heat-generating bodies 100-1 and 100-2 are thermally connected to the outer surface of the heat-receiving block 110, and heat of the heat-generating bodies 100-1 and 100-2 is transferred to the straight section 16 of the container 10 in each of the heat pipe 1-1, 1-2, and 1-3 through the heat-receiving block 110.

The heat-generating bodies 100-1 and 100-2 are thermally connected to each straight section 16 including the one end portion 11 through the heat-receiving block 110 and each straight section 16 functions as an evaporation section (heat-receiving section). In addition, the plurality of heat-releasing fins 50, 50, 50, . . . are thermally connected as heat exchange means to each straight section 17 including the other end portion 13 and each straight section 17 functions as a condensation section (heat-releasing section). Each heat-releasing fin 50 is a thin-plate metal member. Three through-holes 51-1, 51-2, and 51-3 are formed in the thickness direction of the heat-releasing fins 50, and the plurality of heat-releasing fins 50 are thermally connected to the straight sections 17 by fitting and inserting the straight sections 17 of the heat pipes 1-1, 1-2, and 1-3 into the through-holes 51-1, 51-2, and 51-3, respectively.

In the heat sink 207, the straight sections 16 to which the heat-generating bodies 100-1 and 100-2 are thermally connected through the heat-receiving block 110 extend in the first orthogonal direction V1 (front-back direction) that is a first direction orthogonal to the gravity direction G. The straight sections 17 to which the heat-releasing fins 50 are thermally connected extend in a direction that slopes upward at a predetermined angle θ with respect to the second orthogonal direction V2 (right-left direction) that is a direction orthogonal to the gravity direction G and the first orthogonal direction V1. Each bent section 15 is at the same position in the gravity direction G as the corresponding straight section 16 to which the heat-generating body 100 is thermally connected through the heat-receiving block 110.

In the heat sink 207, working fluids of the heat pipes 1-1, 1-2, and 1-3 may be all the same, but different working fluids may be used among the heat pipes 1-1, 1-2, and 1-3. For example, in the heat sink 207, heat input density to the heat pipe 1-2 at the center is thought to be largest due to the positional relation with the heat-generating bodies 100-1 and 100-2, and thus the working fluid of the heat pipe 1-2 may be water and the working fluids of the heat pipes 1-1 and 1-3 on its respective sides may be other than water (for example, working fluids containing hydrofluoroolefin). This is because, from the magnitude relation of latent heat, it is possible to obtain larger heat transfer capacity for a heat pipe with water as the working fluid than for a heat pipe with a working fluid other than water, in a case where other conditions are the same.

With a configuration in which the heat pipe 1-2 with water as the working fluid is sandwiched between the heat pipes 1-1 and 1-3 with a working fluid containing hydrofluoroolefin as in the seventh example embodiment, at low temperature, it is possible to enhance the low-temperature startup performance of the heat pipe 1-2 with water as the working fluid by using heat transfer through the heat pipes 1-1 and 1-3 and heat from the heat-generating body before the heat-generating body temperature becomes too high.

In the above description, the configuration of a heat sink in which a heat pipe with water as the working fluid is disposed between two heat pipes with a working fluid containing hydrofluoroolefin is described, but this configuration can be changed as appropriate in accordance with an environment where the heat sink is installed. For example, in a case where flow of air exists the direction of arrow G in FIG. 21, the working fluid of the heat pipes 1-1 and 1-2 may contain hydrofluoroolefin and the working fluid of the heat pipe 1-3 may be water. With such a configuration, air that flows from the upstream side (in other words, the upper side in FIG. 21) is heated through the two heat pipes 1-1 and 1-2 and then flows nearby the heat pipe 1-3 with water as the working fluid, which is positioned on the downstream side (in other words, the lower side in FIG. 20), and accordingly, it is possible to enhance the low-temperature startup performance of the heat pipe 1-3.

With a configuration in which the heat-generating body 100-1 is disposed directly below the one heat pipe 1-1 as illustrated in FIG. 21, when heat input is concentrated in the one heat pipe 1-1, it is likely to exceed the heat transfer capacity of the heat pipe, increasing the risk of dry-out. Thus, it is preferable to dispose a plurality of (in this example, two) heat pipes 1-2 and 1-3 around the heat-generating body 100-2. With this, it is possible to avoid dry-out of the heat pipe by distributing heat input across the plurality of heat pipes.

The angle θ illustrated in FIG. 21 is preferably 5° to 12° and particularly preferably 7°. In a case where the low-temperature startup performance of a heat pipe with water as the working fluid is to be enhanced, it is preferable to set the angle θ to be large. This is because the circular current speed of water in the container increases and a cooling time before return to the heat-receiving section is shortened, and accordingly, water becomes less likely to freeze in the container.

In a heat sink including a plurality of heat pipes like the heat sink 207 according to the seventh example embodiment, the working fluid of each heat pipe can be appropriately selected in accordance with a design strategy. For example, in a design strategy to reduce heat resistance to lower the temperature of a heat-generating section, a heat pipe that uses a working fluid containing hydrofluoroolefin with low heat resistance may be disposed near the heat-generating section and shortfall in heat transfer capacity may be compensated by a heat pipe with water as the working fluid. In a design strategy to reduce cost, disposition of a heat pipe with water as the working fluid may be prioritized and the number of heat pipes that use a working fluid containing hydrofluoroolefin may be reduced.

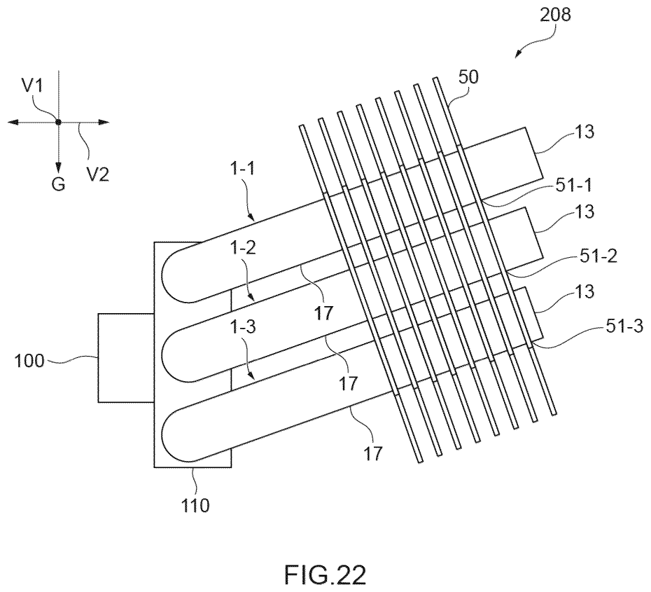

A heat sink according to an eighth example embodiment of the present disclosure will be described next with reference to the accompanying drawings. Note that FIG. 22 is a side view illustrating an overview of the heat sink according to the eighth example embodiment of the present disclosure. Any constituent component similar to that described in the seventh example embodiment is denoted by the same reference sign and description thereof is omitted.

In a heat sink 208 according to the eighth example embodiment, the spacing between the heat pipes 1-1, 1-2, and 1-3 that are adjacent is set to be smaller than the spacing between the heat pipes 1-1, 1-2, and 1-3 in the heat sink 207 according to the seventh example embodiment. For example, the spacing may be shorter than the diameter of each heat pipe.

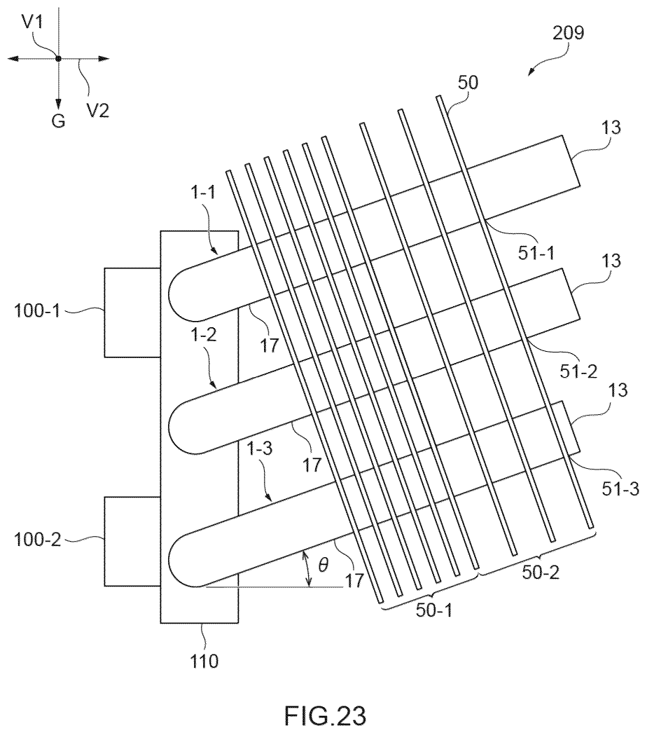

A heat sink according to a ninth example embodiment of the present disclosure will be described next with reference to the accompanying drawings. Note that FIG. 23 is a side view illustrating an overview of the heat sink according to the ninth example embodiment of the present disclosure. Any constituent component similar to that described in the seventh and eighth example embodiments is denoted by the same reference sign and description thereof is omitted.

In a heat sink 209 according to the ninth example embodiment, the spacing between the heat-releasing fins 50 differs between a bottom side 50-1 of the heat pipes and a tip end side 50-2 of the heat pipes as illustrated in FIG. 23, which is difference from the heat sink 207 according to the seventh example embodiment. In other words, the number of fins on the tip end side 50-2 of the heat pipes is reduced compared to the number of fins on the bottom side 50-1 of the heat pipes. Typically, a heat pipe with water as the working fluid has a problem that water is likely to freeze before vapor having reached a condensation section on the end portion 13 side in the container is condensed and returned to a heat-receiving section. The heat dissipation amount is smaller with the fins on the tip end side 50-2 of the heat pipes in the heat sink 209 than with the fins on the bottom side 50-1, and accordingly, the temperature of water as the working fluid is likely to increase and thus it is possible to enhance the startup performance of the heat pipes. Moreover, the movement distance of water in the container decreases, and accordingly, the maximum heat transfer capacity increases. However, heat-radiating performance from the fins degrades.

Other example embodiments of the heat pipe of the present disclosure will be described next. In the heat pipes according to the above-described first and second example embodiments, the shape of the container, which is a tubular body, in the longitudinal direction is a shape including a bent section, but instead, the shape of the container, which is a tubular body, in the longitudinal direction may be a straight shape without a bent section.

In a case where the shape of the container in the longitudinal direction is straight, the encapsulated amount of a working fluid containing hydrofluoroolefin is not particularly limited but is preferably a encapsulated amount with which the working fluid has a cross-sectional area that is 40% or more of the cross-sectional area of a hollow section that is the internal space of the heat pipe in at least one section among sections of the heat pipe in the direction orthogonal to the longitudinal direction when the longitudinal direction of the heat pipe is a direction orthogonal to the direction of gravity from the standpoint to provide excellent heat transfer characteristics to the heat pipe, is further preferably an encapsulated amount with which the working fluid has a cross-sectional area that is 50% or more of the cross-sectional area of the hollow section from the standpoint that the heat transfer characteristics of the heat pipe further improve, and is particularly preferably an encapsulated amount with which the working fluid has a cross-sectional area that is 55% or more of the cross-sectional area of the hollow section.

In the heat pipe according to the above-described third example embodiment, the shape of the container in plan view is a rectangular shape, but the shape of the container in plan view is not particularly limited and may be, for example, a triangular shape, a polygonal shape with five or more sides, a circular shape, a shape including a cutout, or a shape including a bent section instead.

### Examples

Examples of a metal composite compound of the present disclosure will be described next, but the present disclosure is not limited to these examples as long as the present disclosure does not depart from its scope.

The maximum heat transfer capacity was evaluated by evaluation methods listed in Table 1 described below for working fluids using hydrofluoroolefin and heat sinks having the structure of a heat pipe, which are listed in Table 1 described below.

The maximum heat transfer capacity was determined by thermally connecting a heat-generating body to a heat pipe through a heat-receiving block, performing constant heat input in a state in which heat-releasing fins are attached to the other side of the heat pipe, increasing the heat input amount while measuring the temperature of a heat source, measuring a heat input amount at which a heat resistance expressed by an expression described below starts increasing, and setting, as the maximum heat transfer capacity, a heat input amount that is maximum within a range in which the heat resistance does not increase.

$$Heat resistance [ °C / W ] = ( Temperature of heat source - Temperature of external air around heat pipe ) [ °C ] / ( Heat input amount ) [ W ]$$

Note that, in Table 1, “working fluid amount” means the area ratio (%) of the working fluid occupying the cross-sectional area of the internal space of a straight section that functions as the evaporation section (heat-receiving section) of the container in a section in a direction orthogonal to the longitudinal direction of the straight section when the longitudinal direction of the straight section is a direction orthogonal to the direction of gravity. In Table 1, among the sizes of L-shaped and U-shaped heat pipes, “length (x)” means the length of a straight section having the function of the evaporation section (heat-receiving section) among a plurality of straight sections, “length (z)” means the length of a straight section that functions as the condensation section (heat-releasing section) among the plurality of straight sections, and “N/A” means “not applicable”. In Table 1, thickness (y) means the thickness of the internal space of the container of a vapor chamber. In Table 1, “condensation-section upward slope angle” means the angle of the condensation section extending upward in the direction of gravity with respect to a virtual line extending in the direction orthogonal to the direction of gravity, and the number of “evaluation target heat sink” means the reference sign of a heat sink according to an above-described example embodiment.

Evaluation results are listed in Table 1 described below.

TABLE 1

| | | | | Heat transfer section | | | | |
|---|---|---|---|---|---|---|---|---|
| | Working fluid | | | | Heat pipe | | | Vapor |
| | | Working | Critical | Heat | Container | | | chamber |
| | | fluid | point | transfer | inner | Length | Length | Thickness |
| | | amount | temperature | section | diameter | (x) | (z) | (y) |
| Example | Hydrofluoroolefin | % | ° C. | shape | mm | mm | mm | mm |
| Example | HFO-1234ze (E) | 60 | 109 | L shape | 11.7 | 200 | 300 | N/A |
| 17 | | | | | | | | |
| Example 1 | HFO-1234ze (E) | 60 | 109 | L shape | 11.7 | 200 | 300 | N/A |
| Example 2 | HFO-1234ze (E) | 60 | 109 | L shape | 11.7 | 200 | 300 | N/A |
| Example 3 | HFO-1234ze (E) | 60 | 109 | L shape | 11.7 | 200 | 300 | N/A |
| Example 4 | HFO-1234ze (E) | 60 | 109 | L shape | 11.7 | 200 | 300 | N/A |
| Example 5 | HFO-1234ze (Z) | 60 | 153.7 | L shape | 11.7 | 200 | 300 | N/A |
| Example 6 | HFO-1234yf | 60 | 95 | L shape | 11.7 | 200 | 300 | N/A |
| Example 7 | HFO-1234yf | 60 | 95 | L shape | 11.7 | 200 | 300 | N/A |
| Example 8 | HFO-1233zd (E) | 60 | 165.5 | L shape | 11.7 | 200 | 300 | N/A |
| Example 9 | HFO-1234ze (E) | 60 | 109 | L shape | 11.7 | 200 | 300 | N/A |
| Example 10 | HFO-1234ze (E) | 60 | 109 | U shape | 11.7 | 200 | 300 | N/A |
| Example 11 | HFO-1234ze (E) | 60 | 109 | Flat | — | 200 | 300 | 3 |
| | | | | plate | | (Transverse | (Longitudinal | (Thickness) |
| | | | | | | direction | direction | |
| | | | | | | width) | width) | |
| Example 12 | HFO-1234ze (E) | 40 | 109 | L shape | 11.7 | 200 | 300 | N/A |
| Example 13 | HFO-1234ze (E) | 60 | 109 | L shape | 11.7 | 200 | 300 | N/A |
| Example 14 | HFO-1234ze (E) | 60 | 109 | L shape | 11.7 | 200 | 300 | N/A |
| Example 15 | HFO-1234ze (E) | 60 | 109 | L shape | 11.7 | 200 | 300 | N/A |
| Example 16 | HFO-1234ze (E) | 60 | 109 | L shape | 11.7 | 200 | 300 | N/A |

| | | | | Evaluation method | | | Performance |
|---|---|---|---|---|---|---|---|
| | Heat transfer section | | | | | Condensation- | Maximum |
| | Group (fine groove) | | | | Evaluation | section | heat |
| | | | Width | Usage | target | upward | transfer |
| | | Depth | (average) | temperature | heat | slope angle | amount |
| Example | Shape | mm | mm | ° C. | sink | degree | W |
| Example | | None | None | 50 | 201 | 10 | 80 |
| 17 | | | | | | | |
| Example 1 | Trapezoidal | 0.4 | 0.44 | 70 | 201 | 10 | 150 |
| Example 2 | Sintered body of metal powder with | | | 70 | 201 | 10 | 160 |
| | average hole diameter of 0.3 mm | | | | | | |
| Example 3 | The sintered body of metal powder of | | | 70 | 202 | 10 | 60 |
| | Example 2 was formed on the group | | | | | | |
| | of Example 1 | | | | | | |
| Example 4 | The sintered body of metal powder of | | | 70 | 203 | 10 | 130 |
| | Example 2 is formed on the group of | | | | | | |
| | Example 1 | | | | | | |
| Example 5 | Trapezoidal | 0.4 | 0.44 | 70 | 201 | 10 | 110 |
| Example 6 | Trapezoidal | 0.4 | 0.44 | 70 | 201 | 10 | 90 |
| Example 7 | Trapezoidal | 0.4 | 0.44 | 95 | 201 | 10 | 30 |
| Example 8 | Trapezoidal | 0.4 | 0.44 | 95 | 201 | 10 | 120 |
| Example 9 | Trapezoidal | 0.4 | 0.44 | 70 | 201 | 10 | 150 |
| Example 10 | Trapezoidal | 0.4 | 0.44 | 70 | 204 | 10 | 320 |
| Example 11 | Trapezoidal | 0.4 | 0.44 | 70 | 205 | 10 | 300 |
| Example 12 | Trapezoidal | 0.4 | 0.44 | 70 | 201 | 10 | 80 |
| Example 13 | Rectangular | 0.4 | 0.3 | 70 | 201 | 10 | 180 |
| Example 14 | Triangular | 0.4 | 0.3 | 70 | 201 | 10 | 180 |
| Example 15 | Trapezoidal | 0.4 | 0.3 | 70 | 201 | 10 | 180 |
| Example 16 | Trapezoidal | 0.4 | 0.44 | 70 | 206 | 10 | 150 |

From Table 1 described above, even when a heat pipe in which a working fluid containing hydrofluoroolefin is encapsulated was used, the heat sinks of Examples 1 to 17 had favorable heat transfer characteristics with a maximum heat transfer capacity of 30 W or more for an installation posture in which the condensation section extends upward in the direction of gravity. Thus, with Examples 1 to 17, it was found that the flexibility of installation of the heat pipe and the heat sink improves, favorable heat transfer characteristics are obtained, and it is possible to prevent freezing of the working fluid and exhibit excellent circulation characteristics even in a low-temperature operating environment while reducing impact on environment.

In particular, from Example 1 and Example 17, it can be understood that the maximum heat transfer capacity further improved because a fine groove that is a wick structural body is provided on the inner surface of the heat pipe. The maximum heat transfer capacity further improved in Examples 13 to 15 in which the width (average width) of the fine groove is 0.3 mm and the number of fine grooves is larger compared to Example 1 in which the width (average width) of the fine groove is 0.44 mm. From Example 1 and Examples 5 and 6, the maximum heat transfer capacity further improved with trans-1,3,3,3-tetrafluoroprop-1-ene (HFO-1234ze(E)). In Example 1 in which the working fluid amount is 60%, the maximum heat transfer capacity further improved compared to Example 12 in which the working fluid amount is 40%.

From Example 6 and Example 7, the maximum heat transfer capacity of the heat pipe further improved under usage conditions that the usage temperature of the heat pipe is significantly lower than the critical point temperature of the working fluid. Note that the maximum heat transfer capacity in Example 4 is higher than the maximum heat transfer capacity in Example 3 because, in the heat sink 202 that is an evaluation target heat sink of Example 3, a site where a heat-generating body is thermally connected is positioned on the upper side in the direction of gravity relative to a site where heat-releasing fins are thermally connected, compared to the heat sink 203 that is an evaluation target heat sink of Example 4. In other words, this is because the evaluation target heat sink of Example 3 is used in a top-heat configuration.

### INDUSTRIAL APPLICABILITY

A heat pipe and a heat sink of the present disclosure can prevent freezing of a working fluid and exhibit excellent circulation characteristics even in a low-temperature operating environment while reducing impact on environment, and thus can be used in fields of cooling, for example, electronic components such as semiconductor elements mounted in electric and electronic devices like laptop personal computers, servers, and data centers, as well as electronic components such as power semiconductors mounted in power control instruments of trains and the like.

What is claimed is:

1. A heat pipe comprising:
a container including one end portion and another end portion opposite the one end portion, an end face of the one end portion and an end face of the other end portion being sealed;
a wick structural body provided inside the container; and
a working fluid encapsulated inside the container, wherein
the wick structural body includes a fine groove provided on an inner surface of the container and/or a porous body provided on the inner surface of the container, and
the working fluid contains hydrofluoroolefin.

2. The heat pipe according to claim 1, wherein the hydrofluoroolefin is at least one selected from the group consisting of cis-1,3,3,3-tetrafluoroprop-1-ene, trans-1,3,3,3-tetrafluoroprop-1-ene, 2,3,3,3-tetrafluoropropene, (Z)-1,1,1,4,4,4-hexafluorobutene, (E)-1,1,1,4,4,4-hexafluorobutene, trans-1-chloro-3,3,3-trifluoropropene, (Z)-1-chloro-3,3,3-trifluoropropene, and 1-chloro-2,3,3-trifluoropropene.

3. The heat pipe according to claim 1, wherein the hydrofluoroolefin is trans-1,3,3,3-tetrafluoroprop-1-ene.

4. The heat pipe according to claim 1, wherein a temperature of a critical point of the working fluid is equal to or higher than 100° C.

5. The heat pipe according to claim 1, wherein the working fluid is hydrofluoroolefin.

6. The heat pipe according to claim 1, wherein the working fluid contains hydrofluoroolefin, water, and/or alcohol.

7. The heat pipe according to claim 1, wherein the container is a tubular body and an inner diameter of the container is equal to or larger than 3.0 mm and equal to or smaller than 32 mm.

8. The heat pipe according to claim 1, wherein a shape of the container in a longitudinal direction includes a bent section.

9. The heat pipe according to claim 1, wherein the container is planar.

10. The heat pipe according to claim 1, wherein the working fluid has a cross-sectional area that is 50% or more of a cross-sectional area of an internal space of the container in at least one section among sections in a direction orthogonal to a longitudinal direction of the container when a shape of the container in the longitudinal direction is straight and the longitudinal direction of the container is a direction orthogonal to a direction of gravity.

11. The heat pipe according to claim 1, wherein the working fluid has a cross-sectional area that is 50% or more of a cross-sectional area of an internal space of a straight section in at least one section among sections in a direction orthogonal to a longitudinal direction of the straight section when a shape of the container in a longitudinal direction is a shape including the straight section and a bent section and the longitudinal direction of the straight section is a direction orthogonal to a direction of gravity.

12. The heat pipe according to claim 11, wherein the straight section is a site to which a heat-generating body that is a cooling target is thermally connected.

13. The heat pipe according to claim 1, wherein a material of the container is copper, a copper alloy, aluminum, an aluminum alloy, stainless steel, titanium, or a titanium alloy.

14. The heat pipe according to claim 1, wherein the wick structural body is a fine groove provided on the inner surface of the container, and the shape of the fine groove in a direction orthogonal to a longitudinal direction of the container is a rectangular shape, a triangular shape, or a trapezoidal shape.

15. The heat pipe according to claim 14, wherein the shape of the fine groove is a rectangular shape, a depth (H) of the fine groove is equal to or larger than 0.15 mm and equal to or smaller than 0.50 mm, and a width (W) of the fine groove is equal to or larger than 0.15 mm and equal to or smaller than 0.60 mm.

16. The heat pipe according to claim 14, wherein the shape of the fine groove is a triangular shape, a depth (H) of the fine groove is equal to or larger than 0.15 mm and equal to or smaller than 0.50 mm, and a width (W) of the fine groove at a site ((½)H) of ½ of the depth (H) is equal to or larger than 0.15 mm and equal to or smaller than 1.00 mm.

17. The heat pipe according to claim 14, wherein the shape of the fine groove is a trapezoidal shape, a depth (H) of the fine groove is equal to or larger than 0.15 mm and equal to or smaller than 0.50 mm, and an average value of a width (W) of the fine groove is equal to or larger than 0.05 mm and equal to or smaller than 1.00 mm.

18. The heat pipe according to claim 1, wherein a heat-receiving block is further thermally connected to a partial region of the container.

19. The heat pipe according to claim 1, wherein a temperature of an operating environment is equal to or higher than −50° C. and equal to or lower than 90° C.

20. A heat sink comprising:
the heat pipe according to claim 1; and
heat-releasing fins thermally connected to a first region that is a partial region of the container of the heat pipe.

21. The heat sink according to claim 20, wherein a heat-receiving block is further thermally connected to a second region that is another partial region of the container.

22. The heat sink according to claim 20, wherein a temperature of an operating environment is equal to or higher than −50° C. and equal to or lower than 90° C.

23. The heat sink according to claim 20, further comprising a heat pipe with water as the working fluid.

24. The heat sink according to claim 23, wherein an inclination angle of the heat pipe with water as the working fluid is 5° to 12°.

25. The heat sink according to claim 20, wherein spacing between the heat-releasing fins is wider on a tip end side of the heat pipe than on a bottom side of the heat pipe.
